(19) United States
(12) Patent Application Publication
(10) Pub. No.: US 2025/0194271 A1
(43) Pub. Date: Jun. 12, 2025

(54) HYBRID IMAGING SENSOR WITH HIGH SAMPLING POINT DISTRIBUTION

(71) Applicant: OMNIVISION TECHNOLOGIES, INC., Santa Clara, CA (US)

(72) Inventors: Andreas Suess, San Jose, CA (US); Sangjoo Lee, Sunnyvale, CA (US); Bo Mu, San Jose, CA (US); Rui Wang, San Jose, CA (US)

(21) Appl. No.: 18/918,505

(22) Filed: Oct. 17, 2024

Related U.S. Application Data
(60) Provisional application No. 63/608,150, filed on Dec. 8, 2023.

(51) Int. Cl. H01L 27/146; H04N 25/13; H04N 25/78

(52) U.S. Cl. CPC H10F 39/8023; H04N 25/134; H04N 25/78; H10F 39/8053

(57) ABSTRACT

A pixel array includes photodiodes and a color filter array. A first fraction of the photodiodes is included in CIS pixels and a second fraction of the photodiodes is included in hybrid CIS/EVS pixels. The photodiodes are arranged into groupings. The color filter array includes first, second, and third color filters arranged in a mosaic pattern over the photodiodes. Each grouping includes a plurality of subgroupings including a first subgrouping disposed under at least one of the first color filters, a second subgrouping disposed under at least one of the second color filters, and a third subgrouping disposed under at least one of the third color filters. Each of the first, second, and third subgroupings includes at least one CIS pixel, and at least one of the first subgrouping of photodiodes further includes at least one hybrid CIS/EVS pixel disposed under at least one of the first color filters.

### CROSS-REFERENCE TO RELATED APPLICATIONS

The present application claims the benefit of U.S. Provisional Patent Application No. 63/608,150, filed Dec. 8, 2023, the disclosure of which is incorporated herein by reference in its entirety.

### TECHNICAL FIELD

This disclosure relates generally to image sensors, and in particular but not exclusively, relates to hybrid image sensors with high sampling point distribution.

### BACKGROUND

Image sensors have become ubiquitous and are now widely used in digital cameras, cellular phones, security cameras, as well as in medical, automotive, and other applications. As image sensors are integrated into a broader range of electronic devices, it is desirable to enhance their functionality, performance metrics, and the like in as many ways as possible (e.g., resolution, power consumption, dynamic range) through both device architecture design as well as image acquisition processing. The technology used to manufacture image sensors has continued to advance at a great pace. For example, the demands of higher resolution and lower power consumption have encouraged the further miniaturization and integration of these devices.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to produce digital images (e.g., image data) representing the external scene. The analog image signals on the bitlines are coupled to readout circuits, which include input stages having analog-to-digital conversion (ADC) circuits to convert those analog image signals from the pixel array into the digital image signals.

### BRIEF DESCRIPTION OF THE DRAWINGS

Non-limiting and non-exhaustive embodiments of the present disclosure are described with reference to the following figures, wherein like reference numerals refer to like parts throughout the various views unless otherwise specified.

FIG. 1 illustrates one example of a stacked hybrid complementary metal oxide semiconductor (CMOS) image sensor (CIS) with event-based vision sensor (EVS) system in accordance with the teachings of the present disclosure.

FIG. 2 illustrates one example of a pixel circuit with a quad Bayer filter array of an example hybrid imaging sensor in accordance with the teachings of the present disclosure.

FIG. 3 schematically illustrates one example of a pair of pixels of an example hybrid imaging sensor in accordance with the teachings of the present disclosure.

FIG. 4 schematically illustrates one example of a plurality of pixel circuits of an example hybrid imaging sensor in accordance with the teachings of the present disclosure.

FIG. 5 illustrates one example of a pixel circuit with a quad Bayer filter array of an example hybrid imaging sensor in accordance with the teachings of the present disclosure.

FIG. 6 illustrates one example of a pixel circuit with a quad Bayer filter array of an example hybrid imaging sensor in accordance with the teachings of the present disclosure.

FIG. 7 illustrates one example of a pixel circuit with a quad Bayer filter array of an example hybrid imaging sensor in accordance with the teachings of the present disclosure.

FIG. 8 illustrates one example of a pixel circuit with a quad Bayer filter array and dual phase detection (DPD) capability of an example hybrid imaging sensor in accordance with the teachings of the present disclosure.

FIG. 9 illustrates one example of a pixel circuit with a quad RGBC color filter array of an example hybrid imaging sensor in accordance with the teachings of the present disclosure.

FIG. 10 illustrates one example of a pixel circuit with a quad RGBC color filter array of an example hybrid imaging sensor in accordance with the teachings of the present disclosure.

FIG. 11 illustrates one example of a pixel circuit with a quad Bayer filter array of an example hybrid imaging sensor in accordance with the teachings of the present disclosure.

FIG. 12 illustrates one example of a pixel circuit with a quad Bayer filter array of an example hybrid imaging sensor in accordance with the teachings of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present disclosure. In addition, common but well-understood elements that are useful or necessary in a commercially feasible embodiment are often not depicted in order to facilitate a less obstructed view of these various embodiments of the present disclosure.

### DETAILED DESCRIPTION

### I. Overview

Examples directed to an imaging system with a pixel circuit providing simultaneous hybrid functionality with high sampling point distribution are disclosed. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

Reference throughout this specification to “one example” or “one embodiment” means that a particular feature, structure, or characteristic described in connection with the example is included in at least one example of the present disclosure. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Spatially relative terms, such as “beneath,” “below,” “over,” “under,” “above,” “upper,” “top,” “bottom,” “left,” “right,” “center,” “middle,” and the like, may be used herein for case of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein interpreted accordingly. In addition, it will also be understood that when an element is referred to as being “between” two other elements, it can be the only element between the two other elements, or one or more intervening elements may also be present.

It will be further understood that, although the terms first, second, third, etc., may be used herein to describe various elements, these elements should not be limited by these terms and should not be used to determine the process sequence or formation order of associated elements. Unless indicated otherwise, these terms are merely used to distinguish one element from another clement. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

As will be discussed, various examples of an imaging system with a pixel circuit providing simultaneous hybrid functionality (e.g., simultaneous image/video capturing and event driven sensing capabilities) with high sampling point distribution are disclosed. Although normal image/video sensors offer great image and/or video capturing capabilities, one of the limitations with normal image/video sensors is that normal image sensors do not provide ultra-high frame rates and ultra-high speed capture capabilities that may be useful in a variety of applications such as machine vision, gaming, and artificial intelligence sensing areas. Attempts to provide typical image/video sensors with such ultra-high frame rates and ultra-high speed capabilities have resulted in compromised solutions that provide poor quality image captures compared to their normal image sensor counterparts.

It is appreciated that circuit designs in accordance with the teachings of the present disclosure address at least some of the issues discussed above. For example, an image sensor disclosed herein can operate in a hybrid mode in which the image sensor simultaneously provides great image and video capture capabilities using a first set of pixels, and senses events at ultra-high frame rates and at ultra-high speeds from pixel using a second set of pixels for a wide variety of event driven (or other) applications. Moreover, the first and second sets of pixels can be arranged with high sampling point distribution to provide improved contrast and/or modulation transfer function (MTF) compared to other image sensors.

Thus, as will be shown and described in the various examples below, an example pixel includes a plurality of photodiodes arranged in rows and columns and a color filter array. A first fraction of the plurality of photodiodes are of a CMOS image sensor (CIS) pixel type, and a second fraction of the plurality of photodiodes are of a hybrid CIS/event-based vision sensor (EVS) pixel type. The plurality of photodiodes are arranged into groupings of photodiodes. The color filter array includes a plurality of color filters arranged in a mosaic pattern over the plurality of photodiodes. The color filter array includes first color filters, second color filters, and third color filters. Each grouping of photodiodes includes a plurality of subgroupings of photodiodes including a first subgrouping of photodiodes disposed under at least one of the first color filters, a second subgrouping of photodiodes disposed under at least one of the second color filters, and a third subgrouping of photodiodes disposed under at least one of the third color filters. Each of the first subgrouping of photodiodes, second subgrouping of photodiodes, and third subgrouping of photodiodes includes at least one CIS pixel. Moreover, at least one of the first subgrouping of photodiodes further includes at least one hybrid CIS/EVS pixel disposed under at least one of the first color filters.

In some embodiments, an example pixel circuit includes a pixel array and a color filter. The pixel array includes pixels arranged in rows and columns and each including at least one photodiode, a floating diffusion coupled to the at least one photodiode, and at least one transfer transistor coupled between the at least one photodiode and the floating diffusion. The color filter is disposed over the pixel array and includes color filters disposed over a pixel. Each pixel is coupled to a first readout circuit. As will be discussed in various examples below, the pixels include a first subset of pixels and a second subset of pixels. In various examples, the second subset of pixels are also selectively coupled to a second readout circuit and the first subset of pixels are a remaining subset of the pixels that are not coupled to the second readout circuit. In other words, the second subset of pixels is a subset of a set of all of the pixels that includes some, but not all, of the pixels which are coupled to the first readout circuit in accordance with the teachings of the present disclosure. In each 4×4 grouping of pixels, each row of pixels includes at least one pixel included in the first subset of the pixels (e.g., not coupled to the second readout circuit) and disposed underneath at least one of the color filters.

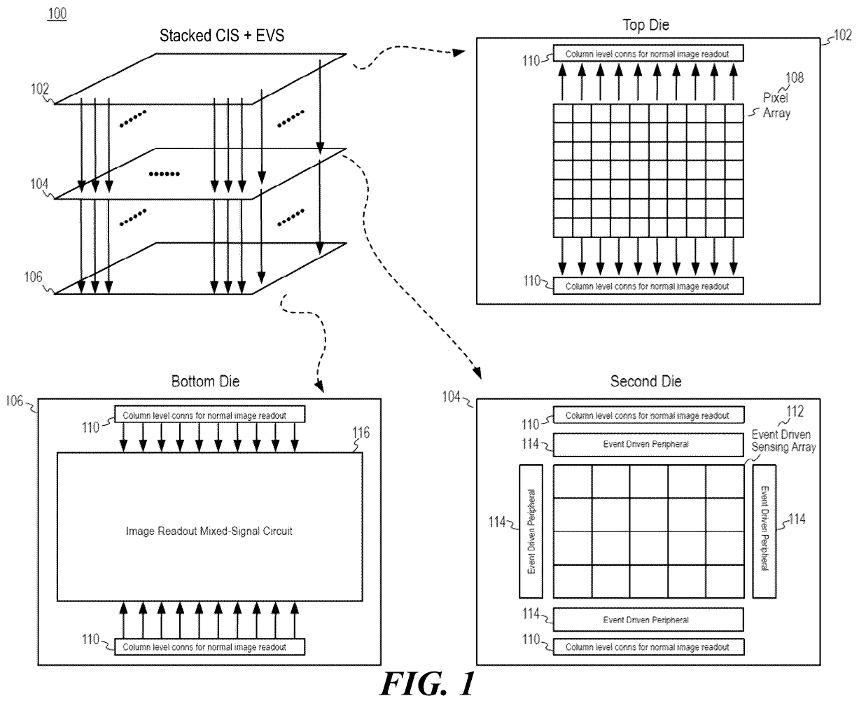

To illustrate, FIG. 1 illustrates one example of a stacked complementary metal oxide semiconductor (CMOS) image sensor (CIS) with event-based vision sensor (EVS) system 100 in accordance with the teachings of the present disclosure. As shown in the depicted example, the stacked CIS with EVS system 100 includes a first die 102, a second die 104, and a third die 106 that are stacked and coupled together in a stacked chip scheme. In various examples, the first die 102, the second die 104, and the third die 106 are semiconductor dice that include a suitable semiconductor material such as silicon. In the example, the first die 102, which may also be referred to as the top die 102 of the stacked CIS with EVS system 100, includes a pixel array 108. The third die 106, which may also be referred to as the bottom die 106 of the stacked CIS with EVS system 100, includes an image readout circuit 116, which may also be referred to as image readout mixed-signal circuitry. The image readout circuit 116 can be coupled to the pixel array 108 of the top die 102 through column level connections for normal image readout 110. In various examples, the column level connections for normal image readout 110 are implemented from column bitlines of the pixel array 108 with through silicon vias (TSVs) that extend between the top die 102 and the bottom die 106, and are routed through the second die 104.

In various examples, the pixel array 108 is a two-dimensional (2D) array including a plurality of pixel cells (also referred to as “pixels”) that each includes at least one photodiode exposed to incident light. As illustrated in the depicted example, the pixels are arranged into rows and columns to acquire image data of a person, place, object, etc., which can then be used to render images and/or video of a person, place, object, etc. As discussed further herein, a first fraction of the pixels are CMOS image sensor (CIS) pixels, and a second fraction of the pixels are hybrid CIS/event-based vision sensor (EVS) pixels. In the example, each CIS pixel includes at least one photosensor such as a photodiode that can be configured to photogenerate image charge in response to the incident light. After each CIS pixel has acquired its image charge, the corresponding analog image charge data is read out by the image readout circuit 116 in the bottom die 106 through the column bit lines. In various examples, the image charge from each row of pixel array 108 may be read out in parallel through column bit lines by the image readout circuit 116.

In various examples, the image readout circuit 116 in the bottom die 106 includes amplifiers, analog to digital converter (ADC) circuitry, associated analog support circuitry, associated digital support circuitry, etc., for normal image readout and processing. In some examples, image readout circuit 116 may also include event driven readout circuitry, which will be described in greater detail below. In operation, the photogenerated analog image charge signals are read out from the pixel cells of pixel array 108, amplified, and converted to digital values in the image readout circuit 116. In some examples, image readout circuit 116 may read out a row of image data at a time. In other examples, the image readout circuit 116 may read out the image data using a variety of other techniques (not illustrated), such as a serial readout or a full parallel readout of all pixels simultaneously. The image data may be stored or even manipulated by applying post image effects (e.g., crop, rotate, remove red eye, adjust brightness, adjust contrast, and the like).

In the depicted example, the second die 104, which may also be referred to as the middle die 104 of the stacked CIS with EVS system 100, includes an event driven sensing array 112 that is coupled to the pixel array 108 in the top die 102. In various examples, the event driven sensing array 112 is coupled to the pixels of the pixel array 108 through one or more pairs of hybrid bonds disposed between the top die 102 and the middle die 104. In one example, the event driven sensing array 112 includes an array of event driven circuits. As will be discussed, in one example, each one of the event driven circuits in the event driven sensing array 112 is coupled to at least one of the plurality of pixels of the pixel array 108 through at least one pair of hybrid bonds between the top die 102 and the middle die 104 to asynchronously detect events that occur in the light that is incident upon the pixel array 108 in accordance with the teachings of the present disclosure.

In some embodiments, the second fraction of the pixels, namely the hybrid CIS/EVS pixels, can be selectively coupled to the event driven readout circuits of the event driven sensing array 112. When operated as EVS pixels, the photosensors of the hybrid CIS/EVS pixels can be used to track changes in the intensity of light incident on the photosensors from an external scene. In particular, the photosensors can photogenerate image charge (electrons or holes) or photocurrent in response to the incident light from the external scene. The photogenerated image can then be provided, via an EVS connection such as a hybrid bond, to a coupled event driven circuit of the event driven sensing array 112. In some embodiments, the event driven circuit includes (i) a photocurrent-to-voltage converter coupled to the photosensor to convert photocurrent generated by the photosensor to a voltage; and (ii) a filter amplifier coupled to the photocurrent-to-voltage converter to generate a filtered and amplified signal in response to the voltage received from the photocurrent-to-voltage converter. The event driven circuit can further include a threshold comparison circuit to determine and generate event detection signals in response to events asynchronously detected in incident light received from the external scene. For example, the threshold comparison circuit may generate an event detection signal when a detected change in the pixel signal at the output of the filter amplifier relative to a reference pixel signal is greater than a predetermined voltage threshold value. It is appreciated that the described event driven readout circuit is one example implementation to read out event signals. Various implementations for readout circuitry and readout schemes for event vision sensor pixels are well known. Thus, details on circuitry and readout techniques for event driven circuits are largely omitted here for the sake of brevity and to avoid obscuring aspects of the present technology.

In various examples, corresponding event detection signals are generated by the event driven circuits in the event driven sensing array 112. The event detection signals may be coupled to be received and processed by an event driven peripheral circuitry 114 which, in one example, is arranged around the periphery of the event driven sensing array 112 in the middle die 104 as shown in FIG. 1. The depicted example also illustrates the column level connections for normal image readout 110 that are routed through the middle die 104 between the top die 102 and the bottom die 106.

### II. Various Examples of Pixel Circuits

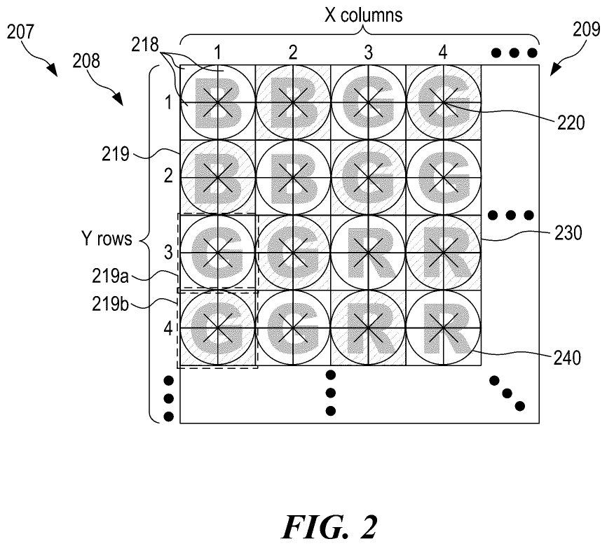

FIG. 2 illustrates one example of an N×N (e.g., 4×4) pixel circuit 207 including a pixel array 208 in accordance with the teachings of the present disclosure. It is appreciated that the pixel array 208 of FIG. 2 may be an example of the pixel array 108 included in the stacked CIS with EVS system 100 as shown in FIG. 1, and that similarly named and numbered elements described above are coupled and function similarly below.

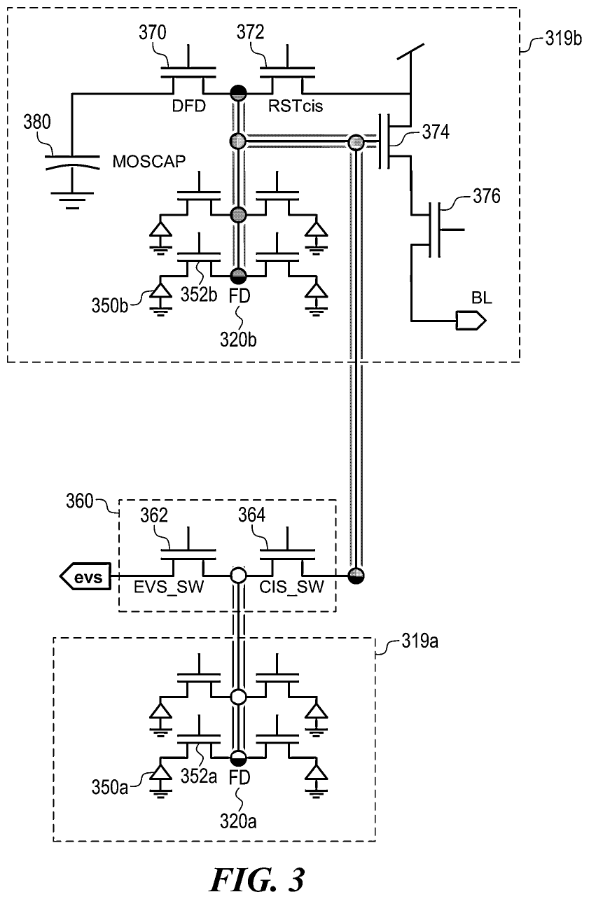

In the illustrated example, the pixel array 208 includes a plurality of pixel cells or pixels 219 arranged in Y rows and X columns. Each pixel 219, for example, can include four subpixels 218 each including a photodiode. Thus, the pixel array 208 includes a plurality of photodiodes arranged in rows and columns, and also arranged into groupings of photodiodes. In the illustrated example, the four photodiodes in the four subpixels 218 are coupled together to share a floating diffusion 220 (represented as an “X” over the four subpixels 218) such that each pixel 219 includes one floating diffusion 220. Thus, each pixel 219 includes quad photodiodes and the pixel array 208 is able to provide quad phase detection (QPD), in which case the top/bottom and/or left/right photodiodes may be read out separately to provide phase information. In various examples, a grouping of photodiodes corresponds to a 4×4 pattern of quad photodiodes (e.g., one such grouping illustrated in FIG. 2). The grouping of photodiodes can include a plurality of subgroupings of photodiodes (e.g., 2×2 subgroupings of photodiodes). In various examples, a subgrouping of photodiodes corresponds to a 2×2 pattern of quad photodiodes (e.g., 4×4 photodiodes as illustrated in FIG. 2). Example circuitries of the pixels 219 are described in further detail below with reference to FIG. 3.

The pixel circuit 207 can also include a color filter array 209 arranged in a mosaic pattern and disposed over the pixel array 208. In one example, the color filter array 209 includes a plurality of color (e.g., R, G, B, C) filters 230 each having one of a plurality of colors (e.g., red, green blue, or clear) and disposed over one of the pixels 219. The color filter array 209 can include first color filters (e.g., blue and/or clear), second color filters (e.g., green and/or clear), and third color filters (e.g., red and/or clear). Each of the first color filters, the second color filters and third color filters may be configured to have different photoresponses. A particular photoresponse may refer to the color filter having a high sensitivity to certain portions of the electromagnetic spectrum while simultaneously having low sensitivity to other portions of the spectrum. A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 2, the color filter array 209 comprises a quad Bayer filter array such that four color filters 230 of the same color are disposed over a 2×2 grouping of the pixels 219 arranged in two adjacent rows and two adjacent columns. For example, the pixels 219 in rows 1-2 and columns 1-2 are disposed underneath blue (e.g., first) color filters 230 (marked by “B”), the pixels 219 in (i) rows 1-2 and columns 3-4 and (ii) rows 3-4 and columns 1-2 are disposed underneath green (e.g., second) color filters 230 (marked by “G”), and the pixels 219 in rows 3-4 and columns 3-4 are disposed underneath red (e.g., third) color filters 230 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 207 can also include a plurality of microlenses 240 disposed over the pixel array 208 (e.g., over the plurality of photodiodes). In particular, the microlens 240 are sized and distributed such that each microlens 240 is disposed over each pixel 219, or a corresponding 2×2 pattern of photodiodes. The microlenses 240 can help concentrate incident light onto the underlying photodiodes included in the pixels 219, improving the sensitivity and overall image quality of the pixel circuit 207. The microlenses 240 can also reduce crosstalk between adjacent pixels 219, thereby enhancing the ability of the pixel circuit 207 to accurately capture fine details and colors.

Each of the pixels 219 can be coupled to a first readout circuit, such as the image readout circuit 116 shown in FIG. 1. Thus, all of the pixels 219 can be used to provide CIS imaging information. Also, the pixels 219 can include a first subset 219a (patterned in FIG. 2) of the pixels 219 and a second subset 219b of the pixels 219. A second subset is a subset of a set that contains some, but not all, of the elements of the original set. In various examples, each of the pixels 219 can be selectively coupled to a first readout circuit. For example, during hybrid CIS and EVS sensing operations, only the pixels of the second subset 219b are configured to couple to a second readout circuit, such as one of the event driven readout circuits included in the event driven sensing array 112 shown in FIG. 1. During hybrid CIS and EVS sensing operations, the pixels of the first subset 219a are coupled to the first readout circuit, but not to (e.g., are disconnected from) the second readout circuit. Thus, a first fraction of the photodiodes is included in the first subset 219a (e.g., CIS pixels) and a second fraction of the photodiodes is included in the second subset 219b (e.g., hybrid CIS/EVS pixels). In the 4×4 pattern of quad photodiodes example illustrated in FIG. 2, the first subset 219a comprises 50% of the pixels 219 and the second subset 219b comprises 50% of the pixels 219. The second subset 219b of the pixels 219 may be arranged in a checkboard pattern such that the second subset 219b includes pixels 219 in (i) odd-numbered rows and even-numbered columns and (ii) even-numbered rows and odd-numbered columns. One of ordinary skill in the art will appreciate that in other examples, the positions of the pixels in the second subset 219b and the pixels in the first subset 219a can be flipped (e.g., the second subset 219b includes pixels 219 in (i) odd-numbered rows and odd-numbered columns and (ii) even-numbered rows and even-numbered columns).

In various examples, the pixel circuit 207 can be operated in a first mode, a second mode, and a third mode. In the first mode, all of the pixels 219 are configured to provide CIS information, for example by the first readout circuit, such that the pixel circuit 207 provides an image corresponding to an external scene without image quality loss compared to conventional CIS-only pixel circuits. In the second mode, the pixels in the first subset 219a are configured to be coupled to the first readout circuit to continue providing CIS information, and the pixels in the second subset 219b are configured to be coupled to the second readout circuit to provide event detection signals (e.g., provide photocurrent for event detection functionality) and/or other non-CIS information (e.g., change in intensity or motion information). Because the pixels in the second subset 219b are disposed under the RGB filters 230, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 207 simultaneously provides CIS information and non-CIS information. In the third mode, all of the pixels 219 are configured to provide non-CIS information. For example, in the third mode, the pixels in the first subset 219a and the pixels in the second subset 219b can be configured to be coupled to the second readout circuit to provide event detection signals (e.g., provide photocurrent for event detection functionality) and/or other non-CIS information (e.g., change in intensity or motion information).

It is appreciated that in the example N×N (e.g., 4×4) pixel circuit 207 shown in FIG. 2, when the pixels of the second subset 219b are configured to operate in the second mode and provide event detection signals, there are also one or more pixels of the first subset 219a under a filter having the same or similar color spectrum response that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under the hybrid mode are all of the sampling sites (pixels) of any particular color in the 4×4 example pixel circuit 207 sacrificed for EVS functionality in accordance with the teachings of the present disclosure. In other words, for each pixel of the second subset 219b providing event detection signals under the hybrid mode, there is at least a corresponding pixel of the first subset 219a that is disposed under a filter having the same or similar color selectivity in the example 4×4 pixel circuit 207 providing corresponding color imaging information in accordance with the teachings of the present disclosure.

FIG. 3 schematically illustrates a first pixel 319a coupled to a second pixel 319b in accordance with the teachings of the present disclosure. It is appreciated that the first pixel 319a of FIG. 3 may be an example of one of the pixels included in the second subset 219b as shown in FIG. 2, that the second pixel 319b of FIG. 3 may be an example of one of the pixels included in the first subset 219a as shown in FIG. 2, and that similarly named and numbered elements described above are coupled and function similarly below.

In the illustrated example, the first pixel 319a includes four photodiodes 350a (e.g., each corresponding to one of the subpixels 218), four transfer transistors 352a, and a floating diffusion FD 320a. The four photodiodes 350a are each configured to photogenerate image charge in response to incident light, the FD 320a is coupled to receive the image charge from the four photodiodes 350a, and the four transfer transistors 352a are coupled between a corresponding one of the four photodiodes 350a and the FD 320a to transfer the image charge from the corresponding photodiode 350a to the FD 320a.

In the illustrated example, the second pixel 319b includes four photodiodes 350b (e.g., each corresponding to one of the subpixels 218), four transfer transistors 352b, and a floating diffusion FD 320b. The four photodiodes 350b are each configured to photogenerate image charge in response to incident light, the FD 320b is coupled to receive the image charge from the four photodiodes 350b, and the four transfer transistors 352b are coupled between a corresponding one of the four photodiodes 350b and the FD 320b to transfer the image charge from the corresponding photodiode 350b to the FD 320b. In another example, it is appreciated that first pixel 319a may include a different number of photodiodes 350a and transfer transistors 352a, such as for example one, two, etc., photodiodes 350a/transfer gates 352a, and that second pixel 319b may also include a different number of photodiodes 350b and transfer transistors 352b, such as for example one, two, etc., photodiodes 350b/transfer transistors 352b. In some embodiments, the second pixel 319b can also include a dual floating diffusion (DFD) switch 370 (e.g., a transistor as shown, a standard switch, etc.), a reset transistor 372, a source follower transistor 374, and a row select transistor 376. The DFD switch 370 can selectively couple the FD 320b to a MOS capacitor 380 coupled to ground for configuring conversion gain for the respective pixel. The reset transistor 372 can selectively couple the FD 320b to a voltage source (e.g., for reset operations). The source follower transistor 374 includes a gate terminal coupled to the FD 320b. The source follower transistor 374 is coupled between a voltage source (e.g., the same or a different voltage source as or from the voltage source to which the reset transistor 372 is coupled) and the row select transistor 376, which is coupled to a bitline.

The first pixel 319a can be coupled to the second pixel 319b via a mode switch circuit 360 configured to selectively couple the first pixel 319a to (i) the first readout circuit (e.g., a first mode), such as the image readout circuit 116 shown in FIG. 1, (ii) the second readout circuit (e.g., a second mode), such as one of the event driven readout circuits included in the event driven sensing array 112 shown in FIG. 1, or (iii) both the second pixel 319b circuit and the second readout circuit (third mode). In the third mode, the four photodiodes 350a of the first pixel 319a are coupled to the second readout circuit through the EVS switch 362 and the four photodiodes 350b of the second pixel 319b are also coupled to the second readout circuit through a CIS switch 364 and an EVS switch 362. The mode switch circuit 360 can be positioned on the same die as the first pixel 319a and/or the second pixel 319b, or on a different die. The mode switch circuit 360 includes the EVS switch 362 (e.g., a transistor as shown, a standard switch, etc.) and the CIS switch 364 (e.g., a transistor as shown, a standard switch, etc.) each coupled to the FD 320a. The EVS switch 362 can selectively couple the FD 320a to the second readout circuit. The CIS switch 364 can selectively couple the FD 320a to the second pixel 319b, and thus the first readout circuit as described in further detail below.

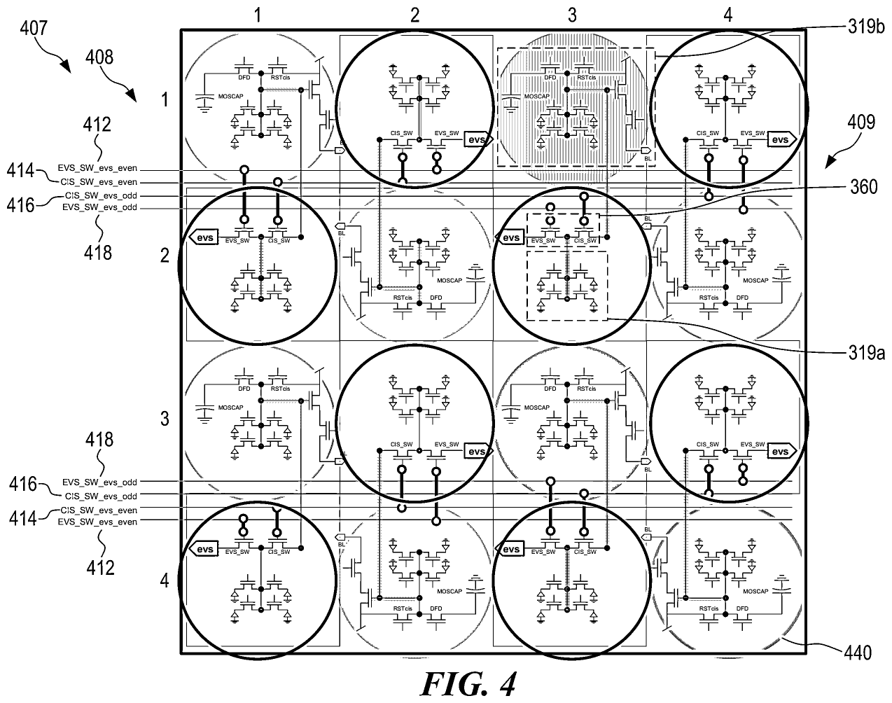

FIG. 4 schematically illustrates one example of a pixel circuit 407 in accordance with the teachings of the present disclosure. It is appreciated that the pixel circuit 407 of FIG. 4 may be an example of the pixel circuit 207 as shown in FIG. 2, and that similarly named and numbered elements described above are coupled and function similarly below.

The pixel circuit 407 can include a pixel array 408, a color filter array 409 disposed over the pixel array 408, and a plurality of microlenses 440 disposed over each of the pixels of the pixel array 408. In the illustrated example, the pixel array 408 includes a pattern or arrangement of first pixels 319a and second pixels 319b as described above in FIG. 3. For instance, as depicted in the example shown in FIG. 4, eight of the first pixels 319a arranged in a checkerboard pattern such that the first pixels 319a are in (i) odd-numbered rows and even-numbered columns and (ii) even-numbered rows and odd-numbered columns. The pixel array 408 also includes eight of the second pixels 319b arranged in a checkerboard pattern offset from the checkerboard pattern of the first pixels 319a. It is appreciated that the pixel array 408 can include a different arrangement and/or ratio of the first pixels 319a and the second pixels 319b. For example, while 8/16 (e.g., 50%) of the pixels in the illustrated pixel array 408 comprise the first pixels 319a and the remaining 8/16 (e.g., 50%) of the pixels in the illustrated pixel array 408 comprise the second pixels 319b, in other examples, 1/16, 2/16, 3/16, 4/16, or other proportions of the pixels in the pixel array can comprise the first pixels 319a.

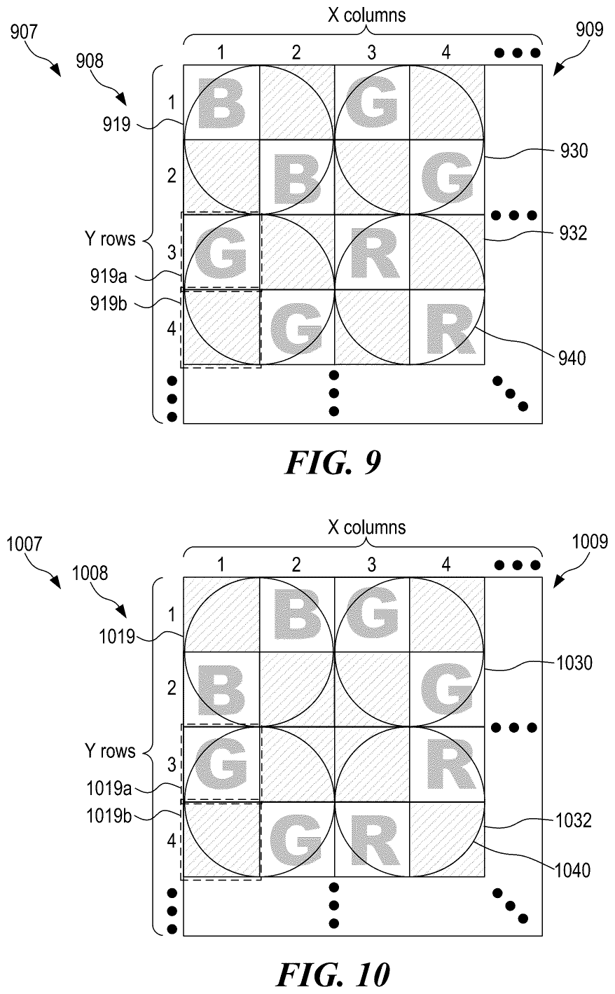

Each second pixel 319b can be disposed underneath a color filter (e.g., the color filter 230) having one of a plurality of colors (e.g., red, green or blue). Each first pixel 319a can be disposed underneath either a color filter (e.g., the color filter 230) having one of a plurality of colors (e.g., red, green or blue), a non-RGB or clear filter, or no filter, as described further herein. In various examples in which the first pixels 319a are disposed underneath color filters, the pixel circuit 407 can be a schematic illustration of or corresponding to the pixel circuit 207 shown in FIG. 2. In various examples in which the first pixels 319a are disposed underneath non-RGB or clear filters (or no filters), the pixel circuit 407 can be a schematic illustration of or corresponding to the pixel circuits shown in FIGS. 9 and 10.

Referring to FIGS. 3 and 4 together, the EVS switches 362 and the CIS switches 364 of the mode switch circuit 360 can be controlled by a plurality of switch signals. In the illustrated example, the EVS switches 362 coupled to the first pixels 319a in columns 1 and 2 are controlled by switch signal EVS_SW_evs_even 412, the CIS switches 364 coupled to the first pixels 319a in columns 1 and 2 are controlled by switch signal CIS_SW_evs_even 414, the CIS switches 364 coupled to the first pixels 319a in columns 3 and 4 are controlled by switch signal CIS_SW_evs_odd 416, and the EVS switches 362 coupled to the first pixels 319a in columns 3 and 4 are controlled by switch signal EVS_SW_evs_odd 418. It is appreciated that the EVS switches 362 and the CIS switches 364 of the mode switch circuit 360 can be controlled by a different combination of switch signals.

Continuing with the examples depicted in FIGS. 3 and 4 together, the pixel circuit 407 can be operated in a first mode by turning on the switch signals 414 and 416 and turning off the switch signals 412 and 418. In the first mode, the image charges photogenerated by the photodiodes 350a of the first pixels 319a are directed entirely, via the CIS switches 364, to the gate terminals of the source follower transistors 374 included in the second pixels 319b vertically adjacent to the particular first pixels 319a. The image charges photogenerated by the photodiodes 350b of the second pixels 319b are also directed entirely to the gate terminals of the corresponding source follower transistors 374. The information subsequently travels to the bitlines and is read out by a first readout circuit, such as the image readout circuit 116 shown in FIG. 1. Therefore, when the pixel circuit 407 is operated in the first mode, all of the pixels 319a, 319b included in the pixel array 408 provide CIS information without image quality loss compared to conventional CIS-only pixel arrays.

The pixel circuit 407 can be operated in a second mode by asserting the switch signals 412 and 418 and un-asserting the switch signals 414 and 416. In the second mode, the image charges photogenerated by the photodiodes 350a of the first pixels 319a are directed entirely, via the EVS switches 362, to the second readout circuit, such as one of the event driven readout circuits included in the event driven sensing array 112 shown in FIG. 1. The image charges photogenerated by the photodiodes 350b of the second pixels 319b continue to be directed entirely to the gate terminals of the corresponding source follower transistors 374 because the CIS switches 362 are off by the corresponding switch signal CIS_SW_evs_even 414 and the switch signal CIS_SW_evs_odd signal 416. The information subsequently travels to the bitlines and is read out by a first readout circuit, such as the image readout circuit 116 shown in FIG. 1. Therefore, when the pixel circuit 407 is operated in the second mode, the signals provided by the first pixels 319a are used by the second readout circuit for gathering and processing non-CIS information (e.g., event detection, phase detection auto-focus, etc.) while the signals provided by the second pixels 319b are used by the first readout circuit for gathering and processing CIS information. In other words, the pixel circuit 407 simultaneously provides CIS information (e.g., from the second pixels 319b) and non-CIS information (e.g., from the first pixels 319a) when operated in the second mode.

The pixel circuit 407 can be operated in a third mode by turning on all of the switch signals 412, 414, 416, 418. In the third mode, because all of the EVS switches 362 and the CIS switches 364 of the mode switch circuits 360 are on, the image charges photogenerated by the photodiodes 350a of the first pixels 319a and by the photodiodes 350b of the second pixels 319b are directed to the second readout circuit, such as one of the event driven readout circuits included in the event driven sensing array 112 shown in FIG. 1. Therefore, when the pixel circuit 407 is operated in the third mode, all of the pixels 319a, 319b included in the pixel array 408 provide EVS information or non-CIS information.

By using separate sets of switch signals for controlling the EVS switches 362 and the CIS switches 364 coupled to the first pixels 319a in columns 1 and 2 (e.g., using switch signals 412 and 414) and in columns 3 and 4 (e.g., using switch signals 416, 418), a finer control of the pixel circuit 407 can be achieved. For example, the portion of the pixel circuit 407 in columns 1 and 2 can be operated in one of the three modes while the portion of the pixel circuit 407 in columns 3 and 4 can be operated in a different one of the three modes. It is appreciated, that a greater or smaller degree of fine control can be achieved by wiring the EVS switches 362 and the CIS switches 364 differently.

In various examples, a set of four pixels may not be coupled to one another to provide neither vertical nor horizontal charge binning, and when operated in a binning mode, the pixel circuit can result in a noise penalty corresponding to 4C1+H+V−SF (groups of 4 cells (2×2) are binned (“4C1”), and additional horizontal and vertical binning is performed by source follower (SF) transistors (“H+V−SF”)). In various examples, the four pixels may be coupled to one another to provide vertical charge binning, and when operated in a binning mode, the pixel circuit can result in a noise penalty corresponding to 2×4+H−SF (groups of 2×4 cells are binned, and additional horizontal binning is performed by source follower (SF) transistors (“H−SF”)). In various examples, the four pixels may be coupled to one another to provide vertical and horizontal charge binning, and when operated in a binning mode, the pixel circuit can result in noise equivalent to 4×4.

In various examples, a set of two pixels may not be coupled to one another to provide neither vertical nor horizontal charge binning, and when operated in a binning mode, the pixel circuit can result in noise equivalent to 2×2+H−SF (noise penalty due to SFbin). In various examples, the two pixels may be coupled to one another to provide horizontal charge binning, and when operated in a binning mode, the pixel circuit can result in noise equivalent to 4×2.

Referring to FIGS. 2-4 together, in each 4×4 grouping of pixels, each row of pixels includes at least one pixel included in the first subset of the pixels and disposed underneath at least one of the color filters. Additionally, in various examples, in each 4×4 grouping of pixels, each row of pixels includes at least one pixel included in the second subset of the pixels. Additionally or alternatively, in various examples, in each 4×4 grouping of pixels, each column of pixels includes (i) at least one pixel included in the second subset of the pixels and/or (ii) at least one pixel included in the first subset of the pixels and disposed underneath at least one of the color filters. Thus, when the imaging system operates in the second mode described above, this results in a high sampling point distribution for CIS information from the pixels included in the first subset and a high sampling point distribution for event detection, phase detection auto focus (PDAF), or other processing performed exclusively for signals from the pixels included in the second subset. The high sampling point distribution disclosed herein can result in improved contrast and/or modulation transfer function (MTF) compared to other image sensors.

### III. Additional Examples of Pixel Circuits

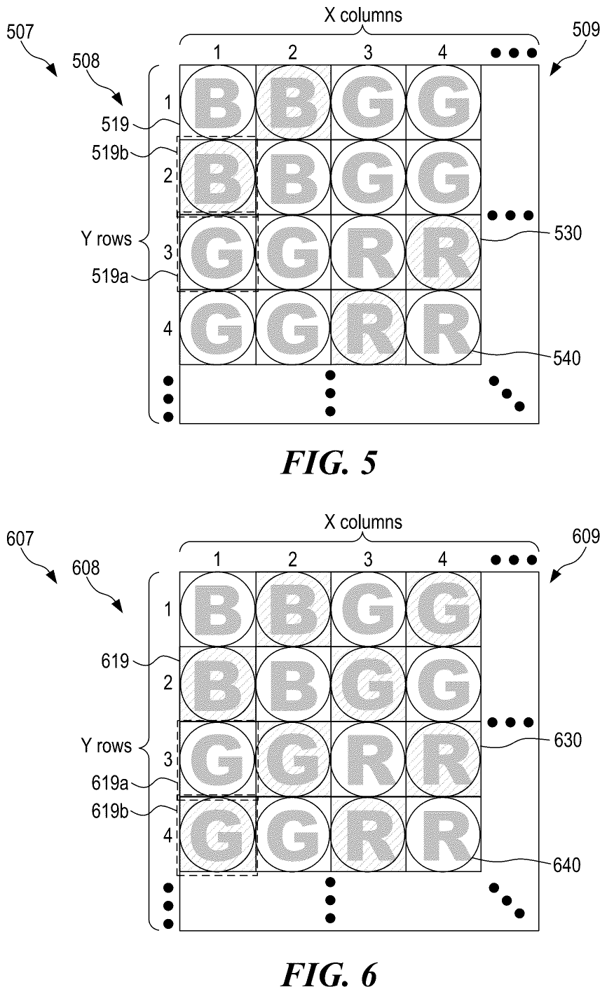

FIG. 5 illustrates one example of an N×N (e.g., 4×4) pixel circuit 507 including a pixel array 508 in accordance with the teachings of the present disclosure. It is appreciated that the pixel array 508 of FIG. 5 may be an example of the pixel array 108 included in the stacked CIS with EVS system 100 as shown in FIG. 1, and that similarly named and numbered elements described above are coupled and function similarly below.

In the illustrated example, the pixel array 508 includes a plurality of pixel cells or pixels 519 arranged in Y rows and X columns. Each pixel 519 can include at least one photodiode and a floating diffusion. Thus, the pixel array 508 includes a plurality of photodiodes arranged in rows and columns, and also arranged into groupings of photodiodes. In various examples, a grouping of photodiodes corresponds to a 4×4 pattern of photodiodes (e.g., one such grouping illustrated in FIG. 5). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 5).

The pixel circuit 507 can also include a color filter array 509 arranged in a mosaic pattern and disposed over the pixel array 508. In one example, the color filter array 509 includes a plurality of color (e.g., RGB) filters 530 each having one of a plurality of colors (e.g., red, green or blue) and disposed over one of the pixels 519. The color filter array 509 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 5, the color filter array 509 comprises a quad Bayer filter array such that four color filters 530 of the same color are disposed over a 2×2 grouping of the pixels 519 arranged in two adjacent rows and two adjacent columns. For example, the pixels 519 in rows 1-2 and columns 1-2 are disposed underneath blue (e.g., first) color filters 530 (marked by “B”), the pixels 519 in (i) rows 1-2 and columns 3-4 and (ii) rows 3-4 and columns 1-2 are disposed underneath green (e.g., second) color filters 530 (marked by “G”), and the pixels 519 in rows 3-4 and columns 3-4 are disposed underneath red (e.g., third) color filters 530 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 507 can also include a plurality of microlenses 540 disposed over the pixel array 508 (e.g., over the plurality of photodiodes). In particular, the microlens 540 are sized and distributed such that each microlens 540 is disposed over each pixel 519, or a corresponding photodiode. The microlenses 540 can help concentrate incident light onto the underlying photodiodes included in the pixels 519, improving the sensitivity and overall image quality of the pixel circuit 507. The microlenses 540 can also reduce crosstalk between adjacent pixels 519, thereby enhancing the ability of the pixel circuit 507 to accurately capture fine details and colors.

Each of the pixels 519 can be coupled to a first readout circuit, such as the image readout circuit 116 shown in FIG. 1. Thus, all of the pixels 519 can be used to provide CIS information. Also, the pixels 519 can include a first subset 519a of the pixels 519 and a second subset 519b (patterned in FIG. 5) of the pixels 519. A second subset is a subset of a set that contains some, but not all, of the elements of the original set. In various examples, only the second subset 519b of the pixels 519 is configured to selectively couple to a second readout circuit, such as one of the event driven readout circuits included in the event driven sensing array 112 shown in FIG. 1 in a certain pixel operation mode e.g., hybrid mode. The pixels in the first subset 519a during a certain pixel operation mode such as hybrid mode are coupled to the first readout circuit, but not to the second readout circuit. Thus, a first fraction of the photodiodes is included in the first subset 519a (e.g., CIS pixels) and a second fraction of the photodiodes is included in the second subset 519b (e.g., hybrid CIS/EVS pixels). In FIG. 5, the first subset 519a comprises 75% of the pixels and the second subset 519b comprises 25% of the pixels, and the second subset 519b of the pixels 519 is arranged in (i) row 1 and column 2, (ii) row 2 and column 1, (iii) row 3 and column 4, and (iv) row 4 and column 3. Thus, the second subset 519b includes 4/16 or 25% of the pixels 519. One of ordinary skill in the art will appreciate that in other examples, the number and/or positions of the pixels in the second subset 519b can be different.

In various examples, the pixel circuit 507 can be operated in a first mode, a second mode, and a third mode. In the first mode, all of the pixels 519 are configured to couple to the first readout circuit to provide CIS imaging information corresponding to an external scene such that the pixel circuit 507 provides an image without image quality loss compared to conventional CIS-only pixel circuits. In the second mode, the pixels in the first subset 519a are configured to couple to the first readout circuit to continue providing CIS information, and the pixels in the second subset 519b are configured to couple to the second readout circuit to provide event detection signals (e.g., provide photocurrent for event detection functionality) and/or other non-CIS information. Because the pixels in the second subset 519b are disposed under the RGB filters 530, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 507 simultaneously provides both CIS imaging information and non-CIS information (e.g., information related to event or change in intensity or motion of an object). In the third mode, all of the pixels 519 are configured to provide non-CIS information. For example, in the third mode, all of the pixels 519 may be configured to connect the second readout circuit through CIS switch 364 and EVS switch illustrated in FIG. 3.

Therefore, it is appreciated that in the example N×N (e.g., 4×4) pixel circuit 507 shown in FIG. 5, when the pixels of the second subset 519b are configured to operate in the second mode and provide event detection signals, there are also one or more pixels of the first subset 519a under a filter having the same color that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that under the second or hybrid mode, at no time are all of the sampling sites of any particular color in the 4×4 example pixel circuit 507 sacrificed for EVS functionality in accordance with the teachings of the present disclosure. In other words, for each pixel of the second subset 519b providing event detection signals, there is a corresponding pixel of the first subset 519a that is disposed under a filter having the same color selectivity in the example 4×4 pixel circuit 507 maintaining image quality (e.g., preserving color-spatial information) in accordance with the teachings of the present disclosure.

FIG. 6 illustrates one example of an N×N (e.g., 4×4) pixel circuit 607 including a pixel array 608 in accordance with the teachings of the present disclosure. It is appreciated that the pixel array 608 of FIG. 6 may be an example of the pixel array 108 included in the stacked CIS with EVS system 100 as shown in FIG. 1, and that similarly named and numbered elements described above are coupled and function similarly below.

In the illustrated example, the pixel array 608 includes a plurality of pixel cells or pixels 619 arranged in Y rows and X columns. Each pixel 619 can include at least one photodiode and a floating diffusion. Thus, the pixel array 608 includes a plurality of photodiodes arranged in rows and columns, and also arranged into groupings of photodiodes. In various examples, a grouping of photodiodes corresponds to a 4×4 pattern of photodiodes (e.g., one such grouping illustrated in FIG. 6). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 6).

The pixel circuit 607 can also include a color filter array 609 arranged in a mosaic pattern and disposed over the pixel array 608. In one example, the color filter array 609 includes a plurality of color (e.g., RGB) filters 630 each having one of a plurality of colors (e.g., red, green or blue) and disposed over one of the pixels 619. The color filter array 609 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 6, the color filter array 609 comprises a quad Bayer filter array such that four color filters 630 of the same color are disposed over a 2×2 grouping of the pixels 619 arranged in two adjacent rows and two adjacent columns. For example, the pixels 619 in rows 1-2 and columns 1-2 are disposed underneath blue (e.g., first) filters 630 (marked by “B”), the pixels 619 in (i) rows 1-2 and columns 3-4 and (ii) rows 3-4 and columns 1-2 are disposed underneath green (e.g., second) color filters 630 (marked by “G”), and the pixels 619 in rows 3-4 and columns 3-4 are disposed underneath red (e.g., third) color filters 630 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 607 can also include a plurality of microlenses 640 disposed over the pixel array 608 (e.g., over the plurality of photodiodes). In particular, the microlens 640 are sized and distributed such that each microlens 640 is disposed over each pixel 619, or a corresponding photodiode. The microlenses 640 can help concentrate incident light onto the underlying photodiodes included in the pixels 619, improving the sensitivity and overall image quality of the pixel circuit 607. The microlenses 640 can also reduce crosstalk between adjacent pixels 619, thereby enhancing the ability of the pixel circuit 607 to accurately capture fine details and colors.

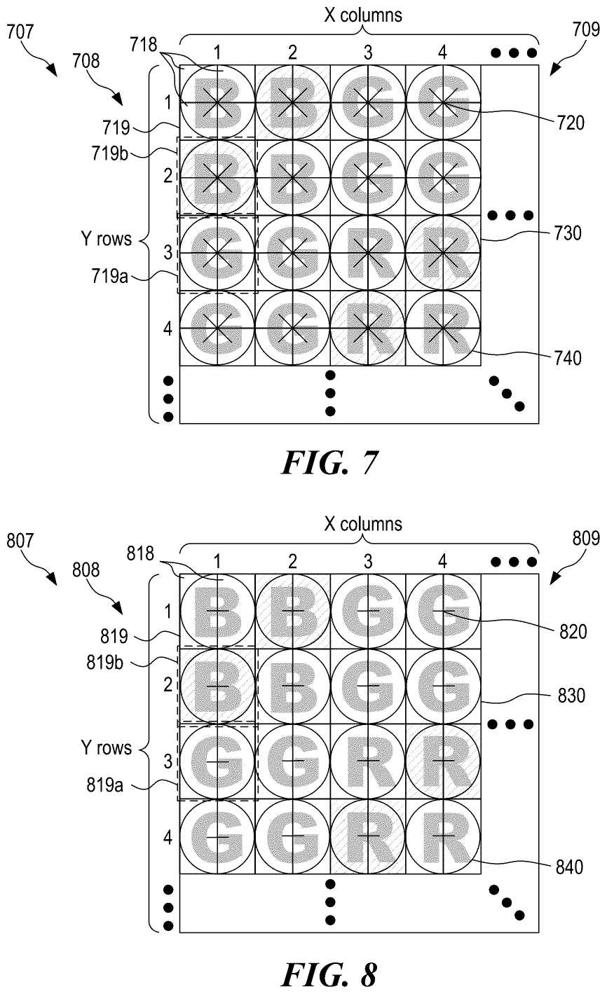

Each of the pixels 619 can be coupled to a first readout circuit, such as the image readout circuit 116 shown in FIG. 1. Thus, all of the pixels 619 can be used to provide CIS information. Also, the pixels 619 can include a first subset 619a of the pixels 619 and a second subset 619b (patterned in FIG. 6) of the pixels 619. A second subset is a subset of a set that contains some, but not all, of the elements of the original set. In various examples, only the second subset 619b of the pixels 619 is configured to couple to a second readout circuit, such as one of the event driven readout circuits included in the event driven sensing array 112 shown in FIG. 1. The pixels in the first subset 619a are coupled to the first readout circuit, but not to the second readout circuit in certain pixel operation mode such as hybrid mode. Thus, a first fraction of the photodiodes is included in the first subset 619a (e.g., CIS pixels) and a second fraction of the photodiodes is included in the second subset 619b (e.g., hybrid CIS/EVS pixels). In FIG. 6, the second subset 619b of the pixels 619 is arranged in a checkboard pattern such that the second subset 619b includes pixels 619 in (i) odd-numbered rows and even-numbered columns and (ii) even-numbered rows and odd-numbered columns. In FIG. 7, the first subset 619a comprises 8 pixels out 16 total pixels or 50% of the pixels and the second subset 619b comprises 50% of the pixels, and the second subset 519b of the pixels 519 includes 8 pixels out of 16 total pixels or 50% of the pixels 519. One of ordinary skill in the art will appreciate that in other examples, the positions of the pixels in the second subset 619b and the pixels in the first subset 619a can be flipped (e.g., the second subset 619b includes pixels 619 in (i) odd-numbered rows and odd-numbered columns and (ii) even-numbered rows and even-numbered columns).

In various examples, the pixel circuit 607 can be operated in a first mode, a second mode, and a third mode. In the first mode, all of the pixels 619 are configured to couple to the first readout circuit to provide CIS information corresponding to an external scene such that the pixel circuit 607 provides an image without image quality loss compared to conventional CIS-only pixel circuits. In the second mode, the pixels in the first subset 619a are configured to couple to the first readout circuit to continue providing CIS information, and the pixels in the second subset 619b are configured to couple to the second readout circuit to provide event detection signals (e.g., provide photocurrent for event detection functionality) and/or other non-CIS information. Because the pixels in the second subset 619b are disposed under the RGB filters 630, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 607 simultaneously provides CIS information and non-CIS information corresponding to the external scene. In the third mode, all of the pixels 619 are configured to couple to the first readout circuit to provide non-CIS information corresponding to the external scene.

Therefore, it is appreciated that in the example N×N (e.g., 4×4) pixel circuit 607 shown in FIG. 6, when the pixels of the second subset 619b are configured to operate in the second mode and provide event detection signals through the second readout circuit, there are also one or more pixels of the first subset 619a under a filter having the same color selectivity that are configured to provide CIS information through the first readout circuit in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under the second or hybrid mode are all of the sampling sites of any particular color in the 4×4 example pixel circuit 607 sacrificed for EVS functionality in accordance with the teachings of the present disclosure. In other words, for each pixel of the second subset 619b providing event detection signals, there is a corresponding pixel of the first subset 619a that is disposed under a filter having the same color selectivity in the example 4×4 pixel circuit 607 in accordance with the teachings of the present disclosure.

FIG. 7 illustrates one example of an N×N (e.g., 4×4) pixel circuit 707 including a pixel array 708 in accordance with the teachings of the present disclosure. It is appreciated that the pixel array 708 of FIG. 7 may be an example of the pixel array 708 included in the stacked CIS with EVS system 100 as shown in FIG. 1, and that similarly named and numbered elements described above are coupled and function similarly below.

In the illustrated example, the pixel array 708 includes a plurality of pixel cells or pixels 719 arranged in Y rows and X columns. Each pixel 719 can include four subpixels 718 each including a photodiode. Thus, the pixel array 708 includes a plurality of photodiodes arranged in rows and columns, and also arranged into groupings of photodiodes. In one example, the four photodiodes in the four subpixels 718 are coupled together to share a floating diffusion 720 (represented as a “X” over the four subpixels 718) such that each pixel 719 includes one floating diffusion 720. Thus, each pixel 719 includes quad photodiodes and the pixel array 708 is able to provide quad phase detection (QPD), in which case the top/bottom and/or left/right photodiodes may be read out separately to provide phase information. In various examples, a grouping of photodiodes corresponds to a 4×4 pattern of quad photodiodes (e.g., one such grouping illustrated in FIG. 7). The grouping of photodiodes can include a plurality of subgroupings of photodiodes (e.g., 2×2 subgroupings of photodiodes). In various examples, a subgrouping of photodiodes corresponds to a 2×2 pattern of quad photodiodes (e.g., 4×4 photodiodes as illustrated in FIG. 7).

The pixel circuit 707 can also include a color filter array 709 arranged in a mosaic pattern and disposed over the pixel array 708. In one example, the color filter array 709 includes a plurality of color (e.g., RGB) filters 730 each having one of a plurality of colors (e.g., red, green or blue) and disposed over one of the pixels 719. The color filter array 709 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 7, the color filter array 709 comprises a quad Bayer filter array such that four color filters 730 of the same color are disposed over a 2×2 grouping of the pixels 719 arranged in two adjacent rows and two adjacent columns. For example, the pixels 719 in rows 1-2 and columns 1-2 are disposed underneath blue (e.g., first) color filters 730 (marked by “B”), the pixels 719 in (i) rows 1-2 and columns 3-4 and (ii) rows 3-4 and columns 1-2 are disposed underneath green (e.g., second) color filters 730 (marked by “G”), and the pixels 719 in rows 3-4 and columns 3-4 are disposed underneath red (e.g., third) color filters 730 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 707 can also include a plurality of microlenses 740 disposed over the pixel array 708 (e.g., over the plurality of photodiodes). In particular, the microlens 740 are sized and distributed such that each microlens 740 is disposed over each pixel 719, or four subpixels 718 or a corresponding 2×2 pattern of photodiodes. The microlenses 740 can help concentrate incident light onto the underlying photodiodes included in the pixels 719, improving the sensitivity and overall image quality of the pixel circuit 707. The microlenses 740 can also reduce crosstalk between adjacent pixels 719, thereby enhancing the ability of the pixel circuit 707 to accurately capture fine details and colors.

Each of the pixels 719 can be coupled to a first readout circuit, such as the image readout circuit 116 shown in FIG. 1. Thus, all of the pixels 719 can be used to provide CIS information. Also, the pixels 719 can include a first subset 719a (patterned in FIG. 7) of the pixels 719 and a second subset 719b of the pixels 719. A second subset is a subset of a set that contains some, but not all, of the elements of the original set. In various examples, only the pixels of the second subset 719b are configured to selectively couple to a second readout circuit under a certain pixel operation mode such as hybrid mode, such as one of the event driven readout circuits included in the event driven sensing array 112 shown in FIG. 1. The pixels of the first subset 719a, under a certain pixel operation mode such as hybrid mode, are coupled to the first readout circuit, but not the second readout circuit. Thus, a first fraction of the photodiodes is included in the first subset 719a (e.g., CIS pixels) and a second fraction of the photodiodes is included in the second subset 719b (e.g., hybrid CIS/EVS pixels). In FIG. 7, the second subset 719b of the pixels 719 is arranged in (i) row 1 and column 2, (ii) row 2 and column 1, (iii) row 3 and column 4, and (iv) row 4 and column 3. Thus, the second subset 719b includes 4/16 or 25% of the pixels 719. One of ordinary skill in the art will appreciate that in other examples, the number and/or positions of the pixels in the second subset 719b can be different.

In various examples, the pixel circuit 707 can be operated in a first mode, a second mode, and a third mode. In the first mode, all of the pixels 719 are configured to couple to the first readout circuit to provide CIS information corresponding to an external scene such that the pixel circuit 707 provides an image without image quality loss compared to conventional CIS-only pixel circuits. In the second mode, the pixels in the first subset 719a are configured to couple to the first readout circuit to continue providing CIS information, and the pixels in the second subset 719b are configured to couple to the second readout circuit to provide event detection signals (e.g., provide photocurrent for event detection functionality) and/or other non-CIS information. Because the pixels in the second subset 719b are disposed under the RGB filters 730, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 707 simultaneously provides CIS information and non-CIS information corresponding to the external scene. In the third mode, all of the pixels 719 are configured to couple to the second readout circuit to provide non-CIS information corresponding to the external scene.

It is appreciated that in the example N×N (e.g., 4×4) pixel circuit 707 shown in FIG. 7, when the pixels of the second subset 719b are configured to operate in the second mode and provide event detection signals, there are also one or more pixels of the first subset 719a under a filter having the same or similar color that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time, under the second or hybrid mode, are all of the sampling sites of any particular color in the 4×4 example pixel circuit 707 sacrificed for EVS functionality maintain color spatial information in accordance with the teachings of the present disclosure. In other words, for each pixel of the second subset 719b providing event detection signals, there is a corresponding pixel of the first subset 719a that is disposed under a filter having the same or similar color selectivity in the example 4×4 pixel circuit 707 in accordance with the teachings of the present disclosure.

FIG. 8 illustrates one example of an N×N (e.g., 4×4) pixel circuit 807 including a pixel array 808 in accordance with the teachings of the present disclosure. It is appreciated that the pixel array 808 of FIG. 8 may be an example of the pixel array 808 included in the stacked CIS with EVS system 100 as shown in FIG. 1, and that similarly named and numbered elements described above are coupled and function similarly below.

In the illustrated example, the pixel array 808 includes a plurality of pixel cells or pixels 819 arranged in Y rows and X columns. Each pixel 819 can include two subpixels 818 each including a photodiode. Thus, the pixel array 808 includes a plurality of photodiodes arranged in rows and columns, and also arranged into groupings of photodiodes. The two photodiodes in the two subpixels 818 are coupled together to share a floating diffusion 820 (represented as a horizontal line extending between the two subpixels 818) such that each pixel 819 includes one floating diffusion 820. Thus, each pixel 819 includes dual photodiodes coupled to a common floating diffusion 820 and the pixel array 808 is able to provide dual phase detection (DPD) for auto-focus operation, in which case the left/right photodiodes may be read out separately to provide phase information. In various examples, a grouping of photodiodes corresponds to a 4×4 pattern of quad photodiodes (e.g., one such grouping illustrated in FIG. 8). The grouping of photodiodes can include a plurality of subgroupings of photodiodes (e.g., 2×2 subgroupings of photodiodes). In various examples, a subgrouping of photodiodes corresponds to a 2×2 pattern of dual photodiodes (e.g., 4×2 photodiodes as illustrated in FIG. 8).

The pixel circuit 807 can also include a color filter array 809 arranged in a mosaic pattern and disposed over the pixel array 808. In one example, the color filter array 809 includes a plurality of color (e.g., RGB) filters 830 each having one of a plurality of colors (e.g., red, green or blue) and disposed over one of the pixels 819. The color filter array 809 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 8, the color filter array 809 comprises a quad Bayer filter array such that four color filters 830 of the same color are disposed over a 2×2 grouping of the pixels 819 arranged in two adjacent rows and two adjacent columns. For example, the pixels 819 in rows 1-2 and columns 1-2 are disposed underneath blue (e.g., first) color filters 830 (marked by “B”), the pixels 819 in (i) rows 1-2 and columns 3-4 and (ii) rows 3-4 and columns 1-2 are disposed underneath green (e.g., second) color filters 830 (marked by “G”), and the pixels 819 in rows 3-4 and columns 3-4 are disposed underneath red (e.g., third) color filters 830 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 807 can also include a plurality of microlenses 840 disposed over the pixel array 808 (e.g., over the plurality of photodiodes). In particular, the microlens 840 are sized and distributed such that each microlens 840 is disposed over each pixel 819, two subpixels 818, or a corresponding 2×1 pattern of photodiodes. The microlenses 840 can help concentrate incident light onto the underlying photodiodes included in the pixels 819, improving the sensitivity and overall image quality of the pixel circuit 807. The microlenses 840 can also reduce crosstalk between adjacent pixels 819, thereby enhancing the ability of the pixel circuit 807 to accurately capture fine details and colors.

Each of the pixels 819 can be coupled to a first readout circuit, such as the image readout circuit 116 shown in FIG. 1. Thus, all of the pixels 819 can be used to provide CIS information. Also, the pixels 819 can include a first subset 819a (patterned in FIG. 8) of the pixels 819 and a second subset 819b of the pixels 819. A second subset is a subset of a set that contains some, but not all, of the elements of the original set. In various examples, under a certain pixel operation mode such as hybrid mode, only the pixels of the second subset 819b are configured to selectively couple to a second readout circuit, such as one of the event driven readout circuits included in the event driven sensing array 112 shown in FIG. 1. The pixels of the first subset 819a are coupled to the first readout circuit, but not the second readout circuit under a certain pixel operation mode such as hybrid mode. Thus, a first fraction of the photodiodes is included in the first subset 819a (e.g., CIS pixels) and a second fraction of the photodiodes is included in the second subset 819b (e.g., hybrid CIS/EVS pixels). In FIG. 8, the second subset 819b of the pixels 819 is arranged in (i) row 1 and column 2, (ii) row 2 and column 1, (iii) row 3 and column 4, and (iv) row 4 and column 3. Thus, the second subset 819b includes 4/16 or 25% of the pixels 819. One of ordinary skill in the art will appreciate that in other examples, the number and/or positions of the pixels in the second subset 819b can be different.

In various examples, the pixel circuit 807 can be operated in a first mode, a second mode, and a third mode. In the first mode, all of the pixels 819 are configured to couple to the first readout circuit to provide CIS information corresponding to an external scene such that the pixel circuit 807 provides an image without image quality loss compared to conventional CIS-only pixel circuits. In the second mode, the pixels in the first subset 819a are configured to couple to the first readout circuit to continue providing CIS information, and the pixels in the second subset 819b are configured to couple to the second readout circuit to provide event detection signals (e.g., provide photocurrent for event detection functionality) and/or other non-CIS information. Because the pixels in the second subset 819b are disposed under the RGB filters 830, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 807 simultaneously provides CIS information and non-CIS information corresponding to the external scene. In the third mode, all of the pixels 819 are configured to couple to the second readout circuit to provide non-CIS information.

It is appreciated that in the example N×N (e.g., 4×4) pixel circuit 807 shown in FIG. 8, when the pixels of the second subset 819b are configured to operate in the second mode and provide event detection signals, there are also one or more pixels of the first subset 819a under a filter having the same or similar color that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under the second or hybrid mode are all of the sampling sites of any particular color in the 4×4 example pixel circuit 807 sacrificed for EVS functionality in accordance with the teachings of the present disclosure. In other words, for each pixel of the second subset 819b providing event detection signals, there is a corresponding pixel of the first subset 819a that is disposed under a filter having the same or similar color selectivity in the example 4×4 pixel circuit 807 in accordance with the teachings of the present disclosure.

FIG. 9 illustrates one example of an N×N (e.g., 4×4) pixel circuit 907 including a pixel array 908 in accordance with the teachings of the present disclosure. It is appreciated that the pixel array 908 of FIG. 9 may be an example of the pixel array 108 included in the stacked CIS with EVS system 100 as shown in FIG. 1, and that similarly named and numbered elements described above are coupled and function similarly below.

In the illustrated example, the pixel array 908 includes a plurality of pixel cells or pixels 919 arranged in Y rows and X columns. Each pixel 919 can include at least one photodiode and a floating diffusion. In various examples, a grouping of photodiodes corresponds to a 4×4 pattern of quad photodiodes (e.g., one such grouping illustrated in FIG. 9). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 9).

The pixel circuit 907 can also include a color filter array 909 arranged in a mosaic pattern and disposed over the pixel array 908. In one example, the color filter array 909 includes a plurality of color (e.g., RGBC) filters 930 each having one of a plurality of colors (e.g., red, green, blue, or clear) and disposed over one of the pixels 919. The color filter array 909 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

FIG. 9 depicts an example in which some, but not all, of the red, green, and blue filters may be replaced with clear filters (e.g., clear, white, panchromatic, etc.) such that clear filters are interspersed among the red, green, and blue filters in accordance with the teachings of the present disclosure. As such, in the example depicted in FIG. 9, the color filter array 909 comprises a quad color array of red color filters, blue color filters, green color filters (RGGB) and an array of clear color filters such that two color filters 930 of the same color (e.g., red, green, or blue) are disposed over two pixels 919 arranged diagonally in adjacent rows and columns. For example, the pixels 919 in (i) row 1 and column 1 and (ii) row 2 and column 2 are disposed underneath blue (e.g., first) color filters 930 (marked by “B”), the pixels 919 in (i) row 1 and column 3, (ii) row 2 and column 4, (iii) row 3 and column 1, and (iv) row 4 and column 2 are disposed underneath green (e.g., second) color filters 930 (marked by “G”), and the pixels 919 in (i) row 3 and column 3 and (ii) row 4 and column 4 are disposed underneath red (e.g., third) color filters 930 (marked by “R”). The rest of the pixels 919, arranged in a checkerboard pattern, are disposed underneath non-RGB or clear filters 932. Alternatively, the rest of the pixels 919 may not be disposed underneath any filter.

The pixel circuit 907 can also include a plurality of microlenses 940 disposed over the pixel array 908 (e.g., over the plurality of photodiodes). In particular, the microlens 940 are sized and distributed such that each microlens 940 is disposed over a 2×2 grouping of pixels 919, or a corresponding subgrouping of photodiodes. The microlenses 940 can help concentrate incident light onto the underlying photodiodes included in the pixels 919, improving the sensitivity and overall image quality of the pixel circuit 907. The microlenses 940 can also reduce crosstalk between adjacent 2×2 groupings of pixels 919, thereby enhancing the ability of the pixel circuit 907 to accurately capture fine details and colors.

Each of the pixels 919 can be coupled to a first readout circuit, such as the image readout circuit 116 shown in FIG. 1. Thus, all of the pixels 919 can be used to provide CIS information. Also, the pixels 919 can include a first subset 919a (patterned in FIG. 9) of the pixels 919 and a second subset 919b of the pixels 919. A second subset is a subset of a set that contains some, but not all, of the elements of the original set. In various examples, under a certain operating mode, only the second subset 919b of the pixels 919 is configured to selectively couple to a second readout circuit, such as one of the event driven readout circuits included in the event driven sensing array 112 shown in FIG. 1. The pixels in the first subset 919a are coupled to the first readout circuit, but not the second readout circuit. Thus, a first fraction of the photodiodes is included in the first subset 919a (e.g., CIS pixels) and a second fraction of the photodiodes is included in the second subset 919b (e.g., hybrid CIS/EVS pixels). As illustrated, the photodiodes included in the second subset 919b may be disposed on non-RGB or clear filters 932. In FIG. 9, the second subset 919b of the pixels 919 is arranged in a checkerboard pattern such that the second subset 919b includes pixels 919 in (i) odd-numbered rows and even-numbered columns and (ii) even-numbered rows and odd-numbered columns. One of ordinary skill in the art will appreciate that in other examples, the positions of the pixels in the second subset 919b and the pixels in the first subset 919a can be flipped (e.g., the second subset 919b includes pixels 919 in (i) odd-numbered rows and odd-numbered columns and (ii) even-numbered rows and even-numbered columns).

In various examples, the pixel circuit 907 can be operated in a first mode, a second mode, and a third mode. In the first mode, all of the pixels 919 are configured to couple to the first readout circuit to provide CIS information corresponding to an external scene such that the pixel circuit 907 provides an image without image quality loss compared to conventional CIS-only pixel circuits. In the second mode, the pixels in the first subset 919a are configured to couple to the first readout circuit to continue providing CIS information, and the pixels in the second subset 919b are configured to couple to the second readout circuit to provide event detection signals and/or other non-CIS information. Therefore, the second mode is a hybrid mode in which the pixel circuit 907 simultaneously provides CIS information and non-CIS information corresponding to the external scene. In the third mode, all of the pixels 919 are configured to couple to the second readout circuit to provide non-CIS information. Disposing the pixels of the second subset 919b underneath the non-RGB or clear filters 932 (or no filters) can help increase the photocurrent generated and/or reduce latency associated with the pixels of second subset 919b when the pixel circuit 907 is operated in the second or third mode (especially in low-light settings where event detection latency can be of particular concern).

Therefore, it is appreciated that in the example N×N (e.g., 4×4) pixel circuit 907 shown in FIG. 9, when the pixels of the second subset 919b are configured to operate in the second mode and provide event detection signals, there are also one or more pixels of the first subset 919a under a filter having the same, or similar color to the color filter that each respective clear filter replaced, that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under a hybrid mode, are all of the sampling sites of any particular color in the 4×4 example pixel circuit 907 sacrificed for EVS functionality in accordance with the teachings of the present disclosure. In other words, for each pixel of the second subset 919b providing event detection signals, there is a corresponding pixel of the first subset 919a that is disposed under a filter having the same, or similar color selectivity to the color filter that each respective clear filter replaced, in the example 4×4 pixel circuit 907 in accordance with the teachings of the present disclosure.

FIG. 10 illustrates one example of an N×N (e.g., 4×4) pixel circuit 1007 including a pixel array 1008 in accordance with the teachings of the present disclosure. It is appreciated that the pixel array 1008 of FIG. 10 may be an example of the pixel array 108 included in the stacked CIS with EVS system 100 as shown in FIG. 1, and that similarly named and numbered elements described above are coupled and function similarly below.

In the illustrated example, the pixel array 1008 includes a plurality of pixel cells or pixels 1019 arranged in Y rows and X columns. Each pixel 1019 can include at least one photodiode and a floating diffusion. In various examples, a grouping of photodiodes corresponds to a 4×4 pattern of quad photodiodes (e.g., one such grouping illustrated in FIG. 10). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 10).

The pixel circuit 1007 can also include a color filter array 1009 arranged in a mosaic pattern and disposed over the pixel array 1008. In one example, the color filter array 1009 includes a plurality of color (e.g., RGGB and clear (C)) filters 1030 each having one of a plurality of colors (e.g., red, green, blue, or clear) and disposed over one of the pixels 1019. The color filter array 1009 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

FIG. 10 depicts an example in which some, but not all, of the red, green, and blue filters may be replaced with clear filters (e.g., clear, white, panchromatic, etc.) such that clear filters are interspersed among the red, green, and blue filters in accordance with the teachings of the present disclosure. As such, in the example depicted in FIG. 10, the color filter array 1009 comprises a quad RGBC color filter array such that two RGB filters 1030 of the same color are disposed over two pixels 1019 arranged diagonally in adjacent rows and columns. For example, the pixels 1019 in (i) row 1 and column 2 and (ii) row 2 and column 1 are disposed underneath blue (e.g., first) color filters 1030 (marked by “B”), the pixels 1019 in (i) row 1 and column 3, (ii) row 2 and column 4, (iii) row 3 and column 1, and (iv) row 4 and column 2 are disposed underneath green (e.g., second) color filters 1030 (marked by “G”), and the pixels 1019 in (i) row 3 and column 4 and (ii) row 4 and column 3 are disposed underneath red (e.g., third) color filters 1030 (marked by “R”). The rest of the pixels 1019 are disposed underneath non-RGB or clear filters 1032. Alternatively, the rest of the pixels 1019 may not be disposed underneath any filter.

The pixel circuit 1007 can also include a plurality of microlenses 1040 disposed over the pixel array 1008 (e.g., over the plurality of photodiodes). In particular, the microlens 1040 are sized and distributed such that each microlens 1040 is disposed over a 2×2 grouping of pixels 1019, or a corresponding subgrouping of photodiodes. The microlenses 1040 can help concentrate incident light onto the underlying photodiodes included in the pixels 1019, improving the sensitivity and overall image quality of the pixel circuit 1007. The microlenses 1040 can also reduce crosstalk between adjacent 2×2 groupings of pixels 1019, thereby enhancing the ability of the pixel circuit 1007 to accurately capture fine details and colors.

Each of the pixels 1019 can be coupled to a first readout circuit, such as the image readout circuit 116 shown in FIG. 1. Thus, all of the pixels 1019 can be used to provide CIS information. Also, the pixels 1019 can include a first subset 1019a (patterned in FIG. 10) of the pixels 1019 and a second subset 1019b of the pixels 1019. A second subset is a subset of a set that contains some, but not all, of the elements of the original set. In various examples, only the second subset 1019b of the pixels 1019 is configured to selectively couple to a second readout circuit, such as one of the event driven readout circuits included in the event driven sensing array 112 shown in FIG. 1. The pixels in the first subset 1019a are coupled to the first readout circuit, but not the second readout circuit. Thus, a first fraction of the photodiodes is included in the first subset 1019a (e.g., CIS pixels) and a second fraction of the photodiodes is included in the second subset 1019b (e.g., hybrid CIS/EVS pixels). In FIG. 10, the second subset 1019b of the pixels 1019 is arranged such that the second subset 1019b includes pixels 1019 in 2×2 groupings (e.g., the pixels 1019 at each corner in the illustrated 4×4 pixel circuit 1007 can form part of 2×2 groupings of pixels 1019 when multiple 4×4 pixel circuits 1007 are arranged together). One of ordinary skill in the art will appreciate that in other examples, the positions of the pixels in the second subset 1019b and the pixels in the first subset 1019a can be flipped.

In various examples, the pixel circuit 1007 can be operated in a first mode, a second mode, and a third mode. In the first mode, all of the pixels 1019 are configured to couple to the first readout circuit to provide CIS information corresponding to an external scene such that the pixel circuit 1007 provides an image without image quality loss compared to conventional CIS-only pixel circuits. In the second mode, the pixels in the first subset 1019a are configured to couple to the first readout circuit to continue providing CIS information, and the pixels in the second subset 1019b are configured to couple to the second readout circuit to provide event detection signals and/or other non-CIS information. Therefore, the second mode is a hybrid mode in which the pixel circuit 1007 simultaneously provides CIS information and non-CIS information corresponding to the external scene. In the third mode, all of the pixels 1019 are configured to couple to the second readout circuit to provide non-CIS information. Disposing the pixels of the second subset 1019b underneath the non-RGB or clear filters 1032 (or no filters) can help increase the photocurrent generated and/or reduce latency associated with the pixels of second subset 1019b when the pixel circuit 1007 is operated in the second or third mode (especially in low-light settings where event detection latency can be of particular concern).

Therefore, it is appreciated that in the example N×N (e.g., 4×4) pixel circuit 1007 shown in FIG. 10, when the pixels of the second subset 1019b are configured to operate in the second mode and provide event detection signals, there are also one or more pixels of the first subset 1019a under a filter having the same, or similar color to the color filter that each respective clear filter replaced, that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under the second or hybrid mode are all of the sampling sites of any particular color in the 4×4 example pixel circuit 1007 sacrificed for EVS functionality in accordance with the teachings of the present disclosure. In other words, for each pixel of the second subset 1019b providing event detection signals, there is a corresponding pixel of the first subset 1019a that is disposed under a filter having the same, or similar color selectivity to the color filter that each respective clear filter replaced, in the example 4×4 pixel circuit 1007 in accordance with the teachings of the present disclosure.

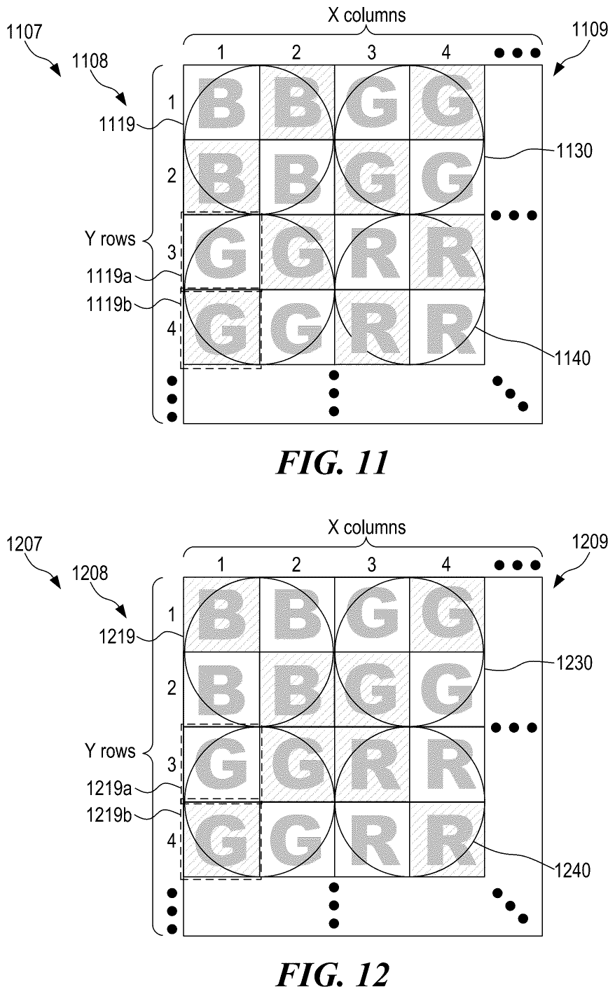

FIG. 11 illustrates one example of an N×N (e.g., 4×4) pixel circuit 1107 including a pixel array 1108 in accordance with the teachings of the present disclosure. It is appreciated that the pixel array 1108 of FIG. 11 may be an example of the pixel array 108 included in the stacked CIS with EVS system 100 as shown in FIG. 1, and that similarly named and numbered elements described above are coupled and function similarly below.

In the illustrated example, the pixel array 1108 includes a plurality of pixel cells or pixels 1119 arranged in Y rows and X columns. Each pixel 1119 can include at least one photodiode and a floating diffusion. In various examples, a grouping of photodiodes corresponds to a 4×4 pattern of quad photodiodes (e.g., one such grouping illustrated in FIG. 11). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 11).

The pixel circuit 1107 can also include a color filter array 1109 arranged in a mosaic pattern and disposed over the pixel array 1108. In one example, the color filter array 1109 includes a plurality of color (e.g., RGB) filters 1130 each having one of a plurality of colors (e.g., red, green or blue) and disposed over one of the pixels 1119. The color filter array 1109 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 11, the color filter array 1109 comprises a quad Bayer filter array such that four color filters 1130 of the same color are disposed over a 2×2 grouping of the pixels 1119 arranged in two adjacent rows and two adjacent columns. For example, the pixels 1119 in rows 1-2 and columns 1-2 are disposed underneath blue (e.g., first) color filters 1130 (marked by “B”), the pixels 1119 in (i) rows 1-2 and columns 3-4 and (ii) rows 3-4 and columns 1-2 are disposed underneath green (e.g., second) color filters 1130 (marked by “G”), and the pixels 1119 in rows 3-4 and columns 3-4 are disposed underneath red (e.g., third) color filters 1130 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 1107 can also include a plurality of microlenses 1140 disposed over the pixel array 1108 (e.g., over the plurality of photodiodes). In particular, the microlens 1140 are sized and distributed such that each microlens 1140 is disposed over a 2×2 grouping of pixels 1119, or a corresponding subgrouping of photodiodes. The microlenses 1140 can help concentrate incident light onto the underlying photodiodes included in the pixels 1119, improving the sensitivity and overall image quality of the pixel circuit 1107. The microlenses 1140 can also reduce crosstalk between adjacent 2×2 groupings of pixels 1119, thereby enhancing the ability of the pixel circuit 1107 to accurately capture fine details and colors.

Each of the pixels 1119 can be coupled to a first readout circuit, such as the image readout circuit 116 shown in FIG. 1. Thus, all of the pixels 1119 can be used to provide CIS information. Also, the pixels 1119 can include a first subset 1119a (patterned in FIG. 11) of the pixels 1119 and a second subset 1119b of the pixels 1119. A second subset is a subset of a set that contains some, but not all, of the elements of the original set. In various examples, under a certain pixel operation mode, such as hybrid mode, only the second subset 1119b of the pixels 1119 is configured to selectively couple to a second readout circuit, such as one of the event driven readout circuits included in the event driven sensing array 112 shown in FIG. 1. The pixels in the first subset 1119a are coupled to the first readout circuit, but not the second readout circuit under a certain pixel mode, such as hybrid mode. Thus, a first fraction of the photodiodes is included in the first subset 1119a (e.g., CIS pixels) and a second fraction of the photodiodes is included in the second subset 1119b (e.g., hybrid CIS/EVS pixels). In FIG. 11, the second subset 1119b of the pixels 1119 is arranged in a checkboard pattern such that the second subset 1119b includes pixels 1119 in (i) odd-numbered rows and even-numbered columns and (ii) even-numbered rows and odd-numbered columns. One of ordinary skill in the art will appreciate that in other examples, the positions of the pixels in the second subset 1119b and the pixels in the first subset 1119a can be flipped (e.g., the second subset 1119b includes pixels 1119 in (i) odd-numbered rows and odd-numbered columns and (ii) even-numbered rows and even-numbered columns).

In various examples, the pixel circuit 1107 can be operated in a first mode, a second mode, and a third mode. In the first mode, all of the pixels 1119 are configured to couple to the first readout circuit to provide CIS information corresponding to an external scene such that the pixel circuit 1107 provides an image without image quality loss compared to conventional CIS-only pixel circuits. In the second mode, the pixels in the first subset 1119a are configured to couple to the first readout circuit to continue providing CIS information, and the pixels in the second subset 1119b are configured to couple to the second readout circuit to provide event detection signals (e.g., provide photocurrent for event detection functionality) and/or other non-CIS information. Because the pixels in the second subset 1119b are disposed under the RGB filters 1130, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 1107 simultaneously provides CIS information and non-CIS information corresponding to the external scene. In the third mode, all of the pixels 1119 are configured to couple to the second readout circuit to provide non-CIS information.

Therefore, it is appreciated that in the example N×N (e.g., 4×4) pixel circuit 1107 shown in FIG. 11, when the pixels of the second subset 1119b are configured to operate in the second mode and provide event detection signals, there are also one or more pixels of the first subset 1119a under a filter having the same, or similar color to the color filter that each respective clear filter replaced, that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under a certain pixel operation mode, such as hybrid mode are all of the sampling sites of any particular color in the 4×4 example pixel circuit 1107 sacrificed for EVS functionality in accordance with the teachings of the present disclosure. In other words, for each pixel of the second subset 1119b providing event detection signals, there is a corresponding pixel of the first subset 1119a that is disposed under a filter having the same, or similar color selectivity to the color filter that each respective clear filter replaced, in the example 4×4 pixel circuit 1107 in accordance with the teachings of the present disclosure.

FIG. 12 illustrates one example of an N×N (e.g., 4×4) pixel circuit 1207 including a pixel array 1208 in accordance with the teachings of the present disclosure. It is appreciated that the pixel array 1208 of FIG. 12 may be an example of the pixel array 108 included in the stacked CIS with EVS system 100 as shown in FIG. 1, and that similarly named and numbered elements described above are coupled and function similarly below.

In the illustrated example, the pixel array 1208 includes a plurality of pixel cells or pixels 1219 arranged in Y rows and X columns. Each pixel 1219 can include at least one photodiode and a floating diffusion. In various examples, a grouping of photodiodes corresponds to a 4×4 pattern of quad photodiodes (e.g., one such grouping illustrated in FIG. 12). The grouping of photodiodes can include a plurality of subgroupings of photodiodes (e.g., 2×2 subgroupings of photodiodes). In various examples, a subgrouping of photodiodes corresponds to a 2×2 pattern of photodiodes (e.g., as illustrated in FIG. 12).

The pixel circuit 1207 can also include a color filter array 1209 arranged in a mosaic pattern and disposed over the pixel array 1208. In one example, the color filter array 1209 includes a plurality of color (e.g., RGB) filters 1230 each having one of a plurality of colors (e.g., red, green or blue) and disposed over one of the pixels 1219. The color filter array 1209 can include first color filters (e.g., blue and/or clear), second color filters (e.g., green and/or clear), and third color filters (e.g., red and/or clear). A first subgrouping of photodiodes can be disposed under at least one of the first color filters, a second subgrouping of photodiodes can be disposed under at least one of the second color filters, and a third subgrouping of photodiodes can be disposed under at least one of the third color filters.

In FIG. 12, the color filter array 1209 comprises a quad Bayer filter array such that four color filters 1230 of the same color are disposed over a 2×2 grouping of the pixels 1219 arranged in two adjacent rows and two adjacent columns. For example, the pixels 1219 in rows 1-2 and columns 1-2 are disposed underneath blue (e.g., first) color filters 1230 (marked by “B”), the pixels 1219 in (i) rows 1-2 and columns 3-4 and (ii) rows 3-4 and columns 1-2 are disposed underneath green (e.g., second) color filters 1230 (marked by “G”), and the pixels 1219 in rows 3-4 and columns 3-4 are disposed underneath red (e.g., third) color filters 1230 (marked by “R”). In other examples, it is appreciated that some, but not all, of the red, green, and blue filters may be replaced with clear filters (e.g., clear, white, panchromatic, etc.) such that clear filters are interspersed among the red, green, and blue filters in accordance with the teachings of the present disclosure.

The pixel circuit 1207 can also include a plurality of microlenses 1240 disposed over the pixel array 1208 (e.g., over the plurality of photodiodes). In particular, the microlens 1240 are sized and distributed such that each microlens 1240 is disposed over a 2×2 grouping of pixels 1219, or a corresponding subgrouping of photodiodes. The microlenses 1240 can help concentrate incident light onto the underlying photodiodes included in the pixels 1219, improving the sensitivity and overall image quality of the pixel circuit 1207. The microlenses 1240 can also reduce crosstalk between adjacent 2×2 groupings of pixels 1219, thereby enhancing the ability of the pixel circuit 1207 to accurately capture fine details and colors.

Each of the pixels 1219 can be coupled to a first readout circuit, such as the image readout circuit 116 shown in FIG. 1. Thus, all of the pixels 1219 can be used to provide CIS information. Also, the pixels 1219 can include a first subset 1219a (patterned in FIG. 12) of the pixels 1219 and a second subset 1219b of the pixels 1219. A second subset is a subset of a set that contains some, but not all, of the elements of the original set. In various examples, under a certain pixel operation mode, such as hybrid mode only the second subset 1219b of the pixels 1219 is configured to selectively couple to a second readout circuit, such as one of the event driven readout circuits included in the event driven sensing array 112 shown in FIG. 1. The pixels in the first subset 1219a are thus coupled to the first readout circuit, but not the second readout circuit under a certain pixel operation mode, such as hybrid mode. Thus, a first fraction of the photodiodes is included in the first subset 1219a (e.g., CIS pixels) and a second fraction of the photodiodes is included in the second subset 1219b (e.g., hybrid CIS/EVS pixels). In FIG. 12, the second subset 1219b of the pixels 1219 is arranged such that the second subset 1219b includes pixels 1219 in 2×2 groupings (e.g., the pixels 1219 at each corner in the illustrated 4×4 pixel circuit 1207 can form part of 2×2 groupings of pixels 1219 (e.g., at center region) when multiple 4×4 pixel circuits 1207 are arranged together in a pixel array). In such examples, pixels included in the second subset 1219b of the pixels 1219 may be surrounded by pixels in the first subset 1219a of the pixels 1219. One of ordinary skill in the art will appreciate that in other examples, the positions of the pixels in the second subset 1219b and the pixels in the first subset 1219a can be flipped.

In various examples, the pixel circuit 1207 can be operated in a first mode, a second mode, and a third mode. In the first mode, all of the pixels 1219 are configured to couple to the first readout circuit to provide CIS information corresponding to an external scene such that the pixel circuit 1207 provides an image without image quality loss compared to conventional CIS-only pixel circuits. In the second mode, the pixels in the first subset 1219a are configured to couple to the first readout circuit to continue providing CIS information, and the pixels in the second subset 1219b are configured to couple to the second readout circuit to provide event detection signals (e.g., provide photocurrent for event detection functionality) and/or other non-CIS information. Because the pixels in the second subset 1219b are disposed under the RGB filters 1230, the non-CIS information can be provided in R+G+G+B or gray, which may result in reduced sensitivity for event detection (or other functionality) in the second mode, but may provide improved image quality in the first mode. Therefore, the second mode is a hybrid mode in which the pixel circuit 1207 simultaneously provides CIS information and non-CIS information corresponding to the external scene. In the third mode, all of the pixels 1219 are configured to couple to the second readout circuit to provide non-CIS information.

Therefore, it is appreciated that in the example N×N (e.g., 4×4) pixel circuit 1207 shown in FIG. 12, when the pixels of the second subset 1219b are configured to operate in the second mode and provide event detection signals, there are also one or more pixels of the first subset 1219a under a filter having the same, or similar color to the color filter that each respective clear filter replaced, that are configured to provide CIS information in accordance with the teachings of the present disclosure. In other words, each of the first subgrouping of photodiodes, second subgrouping of photodiodes, and third subgrouping of photodiodes includes at least one CIS pixel, and at least one of the first subgrouping of photodiodes further includes at least one hybrid CIS/EVS pixel disposed under at least one of the first color filters. In various examples, at least one of the second subgrouping of photodiodes further includes at least one hybrid CIS/EVS pixel disposed under at least one of the second color filters, and/or at least one of the third subgrouping of photodiodes further includes at least one hybrid CIS/EVS pixel disposed under at least one of the third color filters. As such, it is appreciated that at no time under the second or hybrid mode are all of the sampling sites of any particular color in the 4×4 example pixel circuit 1207 sacrificed for EVS functionality in accordance with the teachings of the present disclosure. In other words, for each pixel of the second subset 1219b providing event detection signals, there is a corresponding pixel of the first subset 1219a that is disposed under a filter having the same, or similar color selectivity to the color filter that each respective clear filter replaced, in the example 4×4 pixel circuit 1207 in accordance with the teachings of the present disclosure.

It is appreciated that the pixel circuits illustrated herein and described above are merely examples illustrative of certain features of the present disclosure, and that other pixel circuits are within the scope of the present disclosure. In various examples, a pixel circuit can include 1/16, 2/16, 3/16, 4/16, 5/16, 6/16, 7/16, or other proportions of pixels included in the second subset. In various examples, a pixel circuit can include pixels included in the second subset arranged differently (e.g., in a 4×4 grouping of pixels, the central four pixels and the pixels at each corner can be included in the second subset). In various examples, a pixel circuit can include a Bayer filter array, a quad Bayer filter array, an RGBC filter array, a quad RGBC filter array, or other filter arrays. In various examples, a pixel circuit can include pixels structured and arranged to provide phase detection information (e.g., half-shield PDAF, microlens phase detection, DPD, QPD). Moreover, in examples in which 4×4 groupings of pixels include one or more columns with only one pixel disposed underneath a color filter of a given color, a bitline can be extended across the pixel array diagonally (e.g., as opposed to along the columns) to support analog binning. In various examples, a pixel circuit can include pixel arrangements and structure without advanced pixel shrink technology.

As discussed above, an imaging system configured in accordance with the teachings of the present disclosure can be configured between a first mode, providing only CIS information without image quality loss, a second mode, providing hybrid (e.g., simultaneous CIS and non-CIS) information, and a third mode, providing only non-CIS information. This enables the imaging system to selectively provide various types of information without sacrificing conventional imaging quality, unlike many conventional imaging systems.

In some cases, arranging the pixels included in the second subset in a checkerboard pattern can be preferred due to the manner in which most image sensor systems are used. For example, image sensors (e.g., smartphone cameras) are often held either horizontally or vertically such that horizons or edges (e.g., of walls, doors, windows, etc.) land on a single row or column. If (i) an imaging system is operating in the second (e.g., hybrid) mode, (ii) the pixels included in the second subset cover an entire row or column, and (iii) the incident light from a horizon or edge lands on the row or column occupied entirely by the pixels included in the second subset, the imaging system may be unable to sharply capture that horizon or edge due to the lack of CIS pixels in that row or column. On the other hand, a checkerboard pattern ensures that each row and column includes CIS pixels at all times, regardless of the mode in which the imaging system is operating, to capture those horizons or edges.

Moreover, in the various examples of the pixel circuits illustrated and/or disclosed herein, in each 4×4 grouping of pixels, each row of pixels includes at least one pixel included in the first subset of the pixels and disposed underneath at least one of the color filters. In some examples, in each 4×4 grouping of pixels, each row of pixels includes at least one pixel included in the second subset of the pixels. In some examples, in each 4×4 grouping of pixels, each column of pixels includes at least one pixel included in the first subset of the pixels and disposed underneath at least one of the color filters. In some examples, in each 4×4 grouping of pixels, each column of pixels includes at least one pixel included in the second subset of the pixels.

Because the pixels included in the second subset and the pixels included in the first subset are arranged with high sampling point distribution (e.g., for CIS imaging during the second mode, event detection, phase detection auto focus (PDAF), or other processing), the imaging system can provide improved contrast and/or modulation transfer function (MTF) compared to other image sensors.

### IV. Conclusion

The above description of illustrated examples of the disclosure, including what is described in the Abstract, is not intended to be exhaustive or to limit the disclosure to the precise forms disclosed. While specific examples of the disclosure are described herein for illustrative purposes, various modifications are possible within the scope of the disclosure, as those skilled in the relevant art will recognize.

These modifications can be made to the disclosure in light of the above detailed description. The terms used in the following claims should not be construed to limit the disclosure to the specific examples disclosed in the specification. Rather, the scope of the disclosure is to be determined entirely by the following claims, which are to be construed in accordance with established doctrines of claim interpretation.

1. A pixel array, comprising:
a plurality of photodiodes arranged in rows and columns, wherein a first fraction of the plurality of photodiodes are included in CMOS image sensor (CIS) pixels selectively coupled to a first readout circuit, wherein a second fraction of the plurality of photodiodes are included in hybrid CIS/event based vision sensor (EVS) pixels selectively coupled to one of the first readout circuit or a second readout circuit, wherein the plurality of photodiodes are arranged into groupings of photodiodes; and
a color filter array including a plurality of color filters arranged in a mosaic pattern over the plurality of photodiodes, wherein the color filter array includes first color filters, second color filters, and third color filters,
wherein each grouping of photodiodes includes a plurality of subgroupings of photodiodes including a first subgrouping of photodiodes disposed under at least one of the first color filters, a second subgrouping of photodiodes disposed under at least one of the second color filters, and a third subgrouping of photodiodes disposed under at least one of the third color filters,
wherein at least one photodiode of each of the first subgrouping of photodiodes, second subgrouping of photodiodes, and third subgrouping of photodiodes is included in the CIS pixels, and
wherein at least one photodiode of the first subgrouping of photodiodes is included in the hybrid CIS/EVS pixels.

2. The pixel array of claim 1, wherein first and second ones of the hybrid CIS/EVS pixels are arranged in adjacent rows and in adjacent columns, and wherein at least one photodiode of the second subgrouping of photodiodes is included in the hybrid CIS/EVS pixels.

3. The pixel array of claim 2, wherein at least one photodiode of the third subgrouping of photodiodes is included in the hybrid CIS/EVS pixels.

4. The pixel array of claim 3,
wherein the first color filters include first type color filters having a response to light having a wavelength in a first range and clear color filters, wherein the first subgrouping of photodiodes includes (i) a photodiode included in the CIS pixels and disposed under a first type color filter of the first color filters, and (ii) a photodiode included in the hybrid CIS/EVS pixels and disposed under a clear filter of the first color filters,
wherein the second color filters include second type color filters having a response to light having a wavelength in a second range different from the first range and clear color filters, wherein the second subgrouping of photodiodes includes (i) a photodiode included in the CIS pixels and disposed under a second type color filter of the second color filters, and (ii) a photodiode included in the hybrid CIS/EVS pixels and disposed under a clear filter of the second color filters, and
wherein the third color filters include third type color filters having a response to light having a wavelength in a third range different from the first and second ranges and clear color filters, wherein the third subgrouping of photodiodes includes (i) a photodiode included in the CIS pixels and disposed under a third type color filter of the third color filters, and (ii) a photodiode included in the hybrid CIS/EVS pixels and disposed under a clear filter of the third color filters.

5. The pixel array of claim 4, wherein the first type color filters include blue color filters, wherein the second type color filters include red color filters, and wherein the third type color filters include green color filters.

6. The pixel array of claim 1, wherein each of the groupings of photodiodes includes 2×2 subgroupings of photodiodes.

7. The pixel array of claim 6, wherein each of the subgroupings of photodiodes include 2×2 photodiodes, 4×4 photodiodes, or 4×2 photodiodes.

8. The pixel array of claim 6, wherein the 2×2 subgroupings of photodiodes includes a first subgrouping of photodiodes under the at least one of the first color filters, a second subgrouping of photodiodes under the at least one of the second color filters, and a third subgrouping of photodiodes and a fourth subgrouping of photodiodes under third color filters.

9. A pixel circuit, comprising:
a pixel array including a plurality of pixels arranged in rows and columns, wherein each pixel includes:
at least one photodiode configured to photogenerate image charge in response to incident light;
a floating diffusion coupled to receive the image charge from the at least one photodiode; and
at least one transfer transistor coupled between a corresponding one of the at least one photodiode and the floating diffusion to transfer the image charge from the corresponding one of the at least one photodiode to the floating diffusion; and
a color filter array disposed over the pixel array, wherein the color filter array includes a plurality of color filters each having one of a plurality of colors and disposed over one of the pixels,
wherein each of the plurality of pixels is selectively coupled to a first readout circuit,
wherein the plurality of pixels includes a first subset of the pixels configured to be disconnected from a second readout circuit while coupled to the first readout circuit to read out a first set of data signals, and a second subset of the pixels selectively coupled to the second readout circuit to read out a second set of data signals, and,
wherein, in each N×N grouping of pixels, each row of pixels includes at least one pixel included in the first subset of the pixels and disposed underneath at least one of the color filters.

10. The pixel circuit of claim 9, wherein, in each N×N grouping of pixels, each row of pixels includes at least one pixel included in the second subset of the pixels.

11. The pixel circuit of claim 9, wherein, in each N×N grouping of pixels, each column of pixels includes at least one pixel included in the first subset of the pixels and disposed underneath at least one of the color filters.

12. The pixel circuit of claim 9, wherein, in each N×N grouping of pixels, each column of pixels includes at least one pixel included in the second subset of the pixels.

13. The pixel circuit of claim 9, wherein the color filter array comprises a quad Bayer filter array such that color filters of a same color are disposed over a 2×2 grouping of pixels arranged in adjacent rows and columns, and wherein the pixels included in the second subset are arranged in a checkerboard pattern across the pixel array.

14. The pixel circuit of claim 9, wherein the color filter array comprises a quad color filter array including red color filters (R), blue color filters (B), and green color filters (G), and an array of clear color filters arranged in a manner such that (i) RGB color filters of a same color are disposed over at least two pixels included in the first subset and arranged diagonally in adjacent rows and columns, and (ii) clear filters are disposed over pixels included in the second subset, and wherein the pixels included in the second subset are arranged in a checkerboard pattern across the pixel array.

15. The pixel circuit of claim 9, wherein the first readout circuit comprises an image readout circuit, and wherein the second readout circuit comprises an event detection circuit.

16. The pixel circuit of claim 9, wherein the first subset comprises 50% of the pixels included in the pixel array, and wherein the second subset comprises 50% of the pixels included in the pixel array.

17. An imaging system, comprising:
a pixel circuit including a pixel array including a plurality of pixels arranged in rows and columns, and a color filter array disposed over the pixel array wherein the color filter array includes a plurality of color filters each having one of a plurality of colors and disposed over one of the pixels, wherein each pixel includes:
at least one photodiode configured to photogenerate image charge in response to incident light;
a floating diffusion coupled to receive the image charge from the at least one photodiode; and
at least one transfer transistor coupled between a corresponding one of the at least one photodiode and the floating diffusion to transfer the image charge from the corresponding one of the at least one photodiode to the floating diffusion;
a first readout circuit coupled to each of the plurality of pixels to read out a first set of data signals;
a second readout circuit, wherein the plurality of pixels includes a first subset of the pixels not coupled to the second readout circuit and a second subset of the pixels coupled to the second readout circuit, wherein the second readout circuit is coupled to each of the pixels included in the second subset to read out a second set of data signals; and
a mode switch circuit configured to selectively couple individual ones of the pixels included in the second subset to either the first readout circuit or the second readout circuit based on operation modes of the individual ones of the pixels,
wherein, in each N×N grouping of pixels, each row of pixels includes at least one pixel included in the first subset of the pixels and disposed underneath at least one of the color filters, wherein N being an integer.

18. The imaging system of claim 17, wherein, in each N×N grouping of pixels, each row of pixels includes at least one pixel included in the second subset of the pixels.

19. The imaging system of claim 17, wherein, in each N×N grouping of pixels, each column of pixels includes at least one pixel included in the first subset of the pixels and disposed underneath at least one of the color filters.

20. The imaging system of claim 17, wherein, in each N×N grouping of pixels, each column of pixels includes at least one pixel included in the second subset of the pixels.

21. The imaging system of claim 17, wherein the color filter array comprises a quad Bayer filter array such that color filters of a same color are disposed over a 2×2 grouping of pixels arranged in adjacent rows and columns, and wherein the pixels included in the second subset are arranged in a checkerboard pattern across the pixel array.

22. The imaging system of claim 17, wherein the color filter array comprises a quad color filter array comprising of red color filters (R), green color filters (G), and blue color filters (B), and an array of clear filters arranged in a manner such that (i) RGB filters of a same color are disposed over at least two pixels included in the first subset and arranged diagonally in adjacent rows and columns, and (ii) clear filters are disposed over pixels included in the second subset, and wherein the pixels included in the second subset are arranged in a checkerboard pattern across the pixel array.

23. The imaging system of claim 17, wherein the first readout circuit comprises an image readout circuit, and wherein the second readout circuit comprises an event detection circuit.

24. The imaging system of claim 17, wherein the at least one photodiode includes four photodiodes, wherein the at least one transfer transistor includes four transfer transistors, wherein the four photodiodes of each pixel are disposed under a common microlens, and wherein the pixel circuit is configured to provide quad phase detection (QPD) information.

25. The imaging system of claim 17, wherein the at least one photodiode includes two photodiodes, wherein the at least one transfer transistor includes two transfer transistors, wherein the two photodiodes of each pixel are disposed under a common microlens, and wherein the pixel circuit is configured to provide dual phase detection (DPD) information.
